(19) United States
(12) Patent Application Publication
(10) Pub. No.: US 2026/0118766 A1
(43) Pub. Date: Apr. 30, 2026

(54) Silicon containing coating compositions and uses thereof

(71) Applicant: Pibond Oy, Espoo (FI)

(72) Inventors: Jagadish Salunke, Espoo (FI); Thomas Gädda, Espoo (FI); Kimmo Karaste, Espoo (FI); Hanna Luusua, Espoo (FI); Markus Laukkanen, Espoo (FI); Juha Rantala, Espoo (FI)

(21) Appl. No.: 19/158,071

(22) PCT Filed: Feb. 27, 2024
(86) PCT No.: PCT/FI2024/050070

§ 371 Date: Aug. 20, 2025

(30) Foreign Application Priority Data
Feb. 27, 2023 (FI) 20235233

(51) Int. Cl. G03F 7/09; C08G 77/00; C08G 77/22; G03F 7/00; G03F 7/16; H10P 50/00; H10P 76/20

(52) U.S. Cl. CPC G03F 7/094; C08G 77/22; G03F 7/0005; G03F 7/168; H10P 50/73; H10P 76/20; C08G 77/80

(57) ABSTRACT

Novel functional poly(organosiloxane) resin compositions, methods of producing novel poly(organosiloxane) coating compositions, and coated substrates having improved properties suitable for, e.g., optical applications for achieving predetermined properties of refractive index, absorption coefficient and other properties. Specific embodiments comprise silicon precursors having a substituent that contains a fused aromatic structure exhibiting a butterfly shape, wherein the half-planes defined by aromatic rings joined by intermediate N and S atoms exhibit a dihedral angle of <165 #, whereas the C—S—C angle of the folded thiazine, in particular 1,4-thiazine, ring is less than 110 #. In on embodiment, the silicon precursor has a substituent that comprises an optionally substituted thiazine ring.

### FIELD OF INVENTION

The invention relates to organosilicon resin compositions. In particular, the invention concerns organosilicon polymer compositions useful for coating of optical substrates. The invention also concerns poly(organosiloxane) or polysilsesquioxane resin coatings for use in optical applications for achieving predetermined properties of refractive index, absorption coefficient or other coating properties. The invention also concerns uses of said compositions in semiconductor devices.

### BACKGROUND

Myriads of microelectronic and optoelectronic applications require transparent coatings whose optical properties, mainly the refractive index and the absorption coefficient, need to be optimized either in the device itself, or during the manufacturing of the devices. Such devices and manufacturing processes frequently use a plurality of coatings which are stacked, one upon the other, and then optionally and ultimately covered by a sheet of plastic or glass. In applications, the aim is typically to maximize or improve the performance of the device or its manufacturing process so as to minimize reflections at interfaces between the stacked coatings. Reflections take place typically when the individual coatings exhibit different indexes of refraction. Thus, for example CMOS image sensors require materials with variable refractive indexes to permit light enter the photodiodes with a minimum of losses caused by reflections for improving the quality of the images. Similarly, it is important that coatings are engineered with refractive indexes that maximize the output of light from optoelectronic devices, such as handheld displays, for improving optical clarity and image resolution.

Advanced photolithography employed for manufacturing of state-of-the-art electronic devices is a specific example where control of reflections is important. The photolithography process uses specialized coatings during the imaging to minimize back reflections as well as interference phenomena of single wavelength photons. The continuous increase in demand of increasingly small feature sizes in the semiconductor industry, has led to the development of equipment utilizing deep ultraviolet light with wavelengths of 248 and 193 nm. Such photolithography equipment gives freedom to achieve features as small as down to 50 nm.

Manufacturing of the devices with small feature sizes introduces new challenges in the respect that there can be various errors in the obtained patterns resulting from optical interference due to reflection of light from the underlayer on semiconductor wafer. Also, the variations in photoresist thicknesses due to the topography of underlayer induce errors in the obtained patterns.

Commercially available ARC comprise both inorganic and organic materials. Inorganic ARC materials are beneficial over organic equivalents because using them it is possible to simultaneously achieve several desired properties such as etch selectivity, fill and planarization of substrate topography and anti-reflective functions in a single coating.

US 2007/0148586 A1 relates to hardmask compositions for resist underlayer films, wherein the hardmask compositions include siloxanes which may comprise aryl groups. US 2010/167203 A1 discloses a resist underlayer composition comprising an organosilane polymer, optionally having aryl groups. US 2005/0042538 A1 relates to antireflective hardmask compositions comprising a carbosilane polymer which may include chromophore moieties.

However, there is still a need for developing new materials that can be used in several different applications.

### SUMMARY OF THE INVENTION

It is an object of the present invention to provide poly(organosiloxane) or polysilsesquioxane resin compositions comprising organo-silicon compounds.

It is another object of the present invention to provide methods of producing functional poly(organosiloxane) or polysilsesquioxane resin coating compositions comprising such resins.

It is a third object of the present invention to provide coated substrates comprising poly(organosiloxane) or polysilsesquioxane resins.

It is a fourth object of the present invention to provide silicon precursors capable of use in poly(organosiloxane) or polysilsesquioxane resins.

It is a fifth object of the present invention to provide underlayer coatings comprising poly(organosiloxane) or polysilsesquioxane resins.

It is a sixth object of the present invention to provide substrates comprising coatings having improved properties.

The present invention relates to the use of a novel silicon precursor having a substituent that contains an aromatic structure, comprising in one embodiment fused rings and preferably spatially exhibiting a folded configuration. In one embodiment, the aromatic structure comprises fused rings, in particular one or two lateral aromatic ring(s) fused with a heterocyclic ring containing sulfur and nitrogen, such as a 6-membered thiazine ring.

Thus, in one embodiment, the silicon precursor has a substituent that comprises a thiazine ring with aromatic rings, such as benzene rings, on either or preferably both opposite sides, forming for example a benzo- or dibenzothiazine structure, in particular a dibenzo-1,4-thiazine structure. The fused ring structure can be substituted or unsubstituted, bearing substituents in particular on the aromatic benzene residues.

Spatially, the fused ring structure preferably exhibits a butterfly shape, wherein the half-planes defined by aromatic rings joined by intermediate N and S atoms typically exhibit a dihedral angle of <165°, whereas the C—S—C angle of the folded thiazine, in particular 1,4-thiazine, ring is less than 110° based on literature (Acta Cryst. (1976). B32, 5-10).

Surprisingly, it has been found that compositions of poly(organosiloxane) or polysilsesquioxane resins containing a novel silicon precursor with a substituent that contains an aromatic structure containing both sulfur and nitrogen atoms, as well as solutions and coating compositions comprising them, are capable of achieving a plurality of valuable properties.

The present invention therefore provides for the use of the silicon precursor in organic-inorganic hybrid poly(organosiloxane) or polysilsesquioxane polymers for achieving optical properties.

In addition, the present invention provides for the use of the precursor as a component in underlayer coatings in lithography to adjust the refractive index and the absorption coefficient at a given lithography wavelength.

In one embodiment, the underlayer comprising or consisting of alkoxy-silane-based aromatic butterfly shape compounds possessing dihedral angle of <165° between two benzene rings, sulfur and nitrogen atoms with C—S—C angle of <110° is used as a refractive index enhancer or surface properties modifier, wherein the surface properties include for example hydrophobicity.

In embodiments, polymers comprising the present monomers having a substituent that contains an aromatic structure containing both sulfur and nitrogen atoms are employed for organic-inorganic ARC in deep ultraviolet lithography.

The invention also provides a method of using the present resins containing a novel silicon precursor, in one embodiment having a butterfly shape with a dihedral angle of <165° between two benzene rings and containing an aromatic structure containing both sulfur and nitrogen atoms with a C—S—C angle of <110°, to first coat and cure of an organic underlayer, followed by the coat and cure of the poly(organosiloxane) or polysilsesquioxane resin, followed by coat, bake, exposure and development of a photoresist material, wherein the obtained photoresist pattern is transferred to the poly(organosiloxane) or polysilsesquioxane resin, which again is transferred to the organic underlayer and substrate using selective dry etch process steps.

More specifically, the present invention is mainly characterized by what it stated in the characterizing parts of the independent claims.

Considerable advantages are obtained by the present invention.

It has been found that the resins comprising a novel silicon precursor of the present kind, such as a butterfly shape silicon precursor having a substituent with dihedral angle of <165° between two benzene rings and containing an aromatic structure containing both sulfur and nitrogen atoms with C—S—C angle of <110°, can have numerical attributes which are useful in silicon-based coatings.

Generally, resins provided by embodiments of the invention exhibit high refractive index at visible wavelengths of the spectrum while retaining outstanding mechanical attributes and limited absorption making them useful in imaging and display applications.

Similarly, resins according to embodiments of the invention, containing e.g. a novel butterfly shaped silicon precursor having a substituent that contains an aromatic structure containing both sulfur and nitrogen atoms, have the ability to simultaneously yield coatings with desirable optical, mechanical and compositional properties which make them useful in optical lithography applications.

Further, resins according to embodiments of the invention, containing a novel silicon precursor having a substituent that contains an aromatic structure containing both sulfur and nitrogen atoms, have the ability to simultaneously yield coatings with desirable optical, mechanical and compositional properties while also having a beneficial attribute to the pattern profiles in optical lithography applications.

Solutions according to embodiments of the invention, containing a poly(organosiloxane) or polysilsesquioxane resin containing a novel silicon precursor having a substituent that contains an aromatic structure containing both sulfur and nitrogen atoms, can be used to cast films on semiconductor or other substrates to be used as such to direct light favorable or used in semiconductor fabrication processes to adjust the optical properties of the coating to achieve improved reflectivity control.

In some embodiment, solutions of such embodiments also contribute to the cure process or the pattern shape of the resist coated, exposed and developed on top of the said coating.

Thus, the present solutions can be used for casting of coatings on semiconductor substrates to form a coating that has predetermined optical properties in terms of refractive index and absorption coefficient.

In some embodiments, the present precursors can be employed as additives in underlayer coatings in lithography to simultaneously adjust the refractive index, the absorption coefficient at lithographic wavelengths, etch resistance, as well as to facilitate the cure process, and improve the surface energy of the coating.

An underlayer polymer composition comprising novel aromatic substituents of the present kind, e.g. comprising at least one sulfur and nitrogen containing butterfly shape aromatic derivative exhibiting a dihedral angle of <165° between two benzene rings with C—S—C bond angle of <110°, yields coatings that have high refractive index in the visible wavelengths and can be used in coating compositions to adjust optical constants in lithographic wavelengths. In addition, the present new precursors, in particular the sulfur and nitrogen containing aromatic butterfly shaped derivative, when used as a precursor for a polymer, yields coatings which have surprising beneficial effects in the interfaces of subsequent layers.

Due to process simplicity, good optical performance, room temperature applicability, and time saving the present organic-inorganic hybrid materials are attractive for ARC applications e.g., in displays as well as other technologies where prerequisite to reduce reflection. Additionally, the high silicon content in the organic-inorganic hybrid materials makes them resistant to etching in an oxygen plasma, resulting in efficient pattern transfer onto the underlying organic layer.

Further features and advantages of the present technology will appear from the following detailed description of embodiments.

### BRIEF DESCRIPTION OF THE DRAWINGS

FIG. 1 shows in sideview schematically the principle steps of forming a trilayered lithography stack;

FIG. 2 shows in sideview a four-layered lithography stack; and

FIG. 3 shows the GC-MS of a butterfly shape aromatic compound possessing sulfur and nitrogen atoms with a dihedral angle of <165° between two benzene rings with C—S—C bond angle of <110°.

FIG. 4 shows the applicability of present invention as a functional layer 120 in lithography stack having typical photoresist 110, Silicon hard mask Si-BARC or Silicon oxynitride or metal oxides 130, SOC or CVD carbon or high temperature SOC 140, and substrate 150 respectively.

### EMBODIMENTS

Unless otherwise stated herein or clear from the context, any percentages referred to herein are expressed as percent by weight based on a total weight of the respective composition.

Unless otherwise stated, properties that have been experimentally measured or determined herein have been measured or determined at room temperature. Unless otherwise indicated, room temperature is 25° C.

It must also be noted that, as used in the specification and the appended claims, the singular forms “a,” “an” and “the” include plural referents unless otherwise specified.

As used herein, the term “about” refers to a value which is ±5% of the stated value. As used herein, the term “about” refers to the actual given value, and also to an approximation to such given value that would reasonably be inferred to one of ordinary skill in the art, including approximations due to the experimental and/or measurement conditions for such given value.

Unless otherwise stated, the term “molecular weight” or “average molecular weight” refers to weight average molecular weight (also abbreviated “M_{w}”).

As used herein, the molecular weight has been measured by gel-permeation chromatography using polystyrene standards.

As used herein, unless otherwise stated, the term “viscosity” stands for dynamic viscosity, at 25° C., determined by a rheometer at a 2.5 s⁻¹ shear rate.

The viscosity can be measured with a viscometer, such as a Brookfield or Cole-Parmer viscometer, which rotates a disc or cylinder in a fluid sample and measures the torque needed to overcome the viscous resistance to the induced movement. The rotation can be at any desired rate, such as from 1 to 30 rpm, preferably at 5 rpm, and preferably with the material being measured being at 25° C.

The film contact angle can be measured by using KSV Instruments CAM100. The tool has an inaccuracy of +/−0.1 degrees and determines the angle formed by a water droplet at the boundary where liquid (DI-water), gas (air) and solid (thin film) intersect. A syringe with micro-screw was used to dispense a DI-water droplet on a film (coated typically on a silicon wafer) to determine static contact angle. Further, the contact angle automatically calculated by in built software from still images taken with a camera by using Young-Laplace equation for curve fitting. The resulting static contact angle is the average of left and right-side angle measurements. Three measurements were performed on each sample and the average value reported.

In the present context, the term “precursor” is used synonymously with the term “monomer” to designate a molecule that can, on its own, or as a co-monomer with other monomers be incorporated into polymer, in particular as a part of a linear or branched polymer backbone.

The present materials can be characterized as “polysiloxane resins”, or generally as “poly(organosiloxane) resins, and in particular embodiments as “polyaromatic polysilsesquioxane resins”. Such materials contain residues derived from organic compounds as well as from inorganic compounds, as will be explained below. Further, the present materials contain silanol groups, i.e. groups exhibiting the connectivity Si—O—H. The present materials also contain other functional groups exhibiting connectivity to Si, typically along its main chain, in particular along its main siloxane chain.

In the present context, the term “butterfly shape(d) precursor” stands for a compound having two lateral ring structures, in particular aromatic ring structures, flanking, like wings of a butterfly, a central portion, akin to the body of a butterfly, the lateral ring structures typically extending in two geometrical planes which intersect each other and defining a dihedral angle smaller than 180°, typically 165° or less.

Generally, the dihedral angle between two benzene rings is in the range of 110 to less than 165° and the C—S—C bond angle is in the range of 90 to less than 110°.

Typically, there is about 70-99 mole-% of a novel butterfly shape precursor per repeating unit of the poly(organosiloxane) or polysilsesquioxane resin main chain. In one embodiment, there is, on an average, about 90 to 98 mole-% of the polyaromatic precursor for each unit of the poly(organosiloxane) or polysilsesquioxane resin main chain. These materials made by incorporation of a novel precursor containing nitrogen and sulfur with dihedral angle of <165° between two benzene rings with a C—S—C bond angle of <110° yield coatings with high refractive index with and index of refraction above 1.5, preferably above 1.52, more preferably above 1.55 when measured at a wavelength of 663 nm.

In another embodiment, there are about 1-20 mole-% of the novel precursors per repeating unit of the poly(organosiloxane) or polysilsesquioxane resin main chain. In one further embodiment, there is less than 1 mole-% of the polyaromatic precursor for each unit of the poly(organosiloxane) or polysilsesquioxane resin main chain.

Embodiments of the present technology relate to methods of manufacturing poly(organosiloxane) or polysilsesquioxane resin solutions containing a novel silicon precursor having a substituent that contains an aromatic structure containing both sulfur and nitrogen atoms, in particular exhibiting a dihedral angle of <165° between two benzene rings and with a C—S—C bond angle of <110°, where in hydrolyzable silicon precursors are subjected to hydrolysis/condensation reactions alone or with suitable other silicon containing precursors.

Embodiments also relate to the use of the functional poly(organosiloxane) or polysilsesquioxane solutions to cast coatings on semiconductor substrates in the lithography process to form patterns through subsequent bake, irradiation and development steps. In particular, the invention relates to the ability to control the microstructure of the resin in such way it is industrially feasible and solves the drawbacks of prior art.

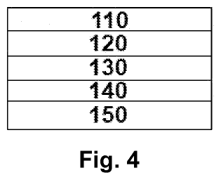

Embodiments of the present technology relate to application of novel silicon containing functional coating in lithography stack layers (FIG. 4). In such scheme, the stack consists of a photoresist layer 110 of 40-50 nm, a functional layer 120 of thickness 5-10 nm, a Si-BARC or Silicon oxynitride or metal oxide layer 130 of 20-50 nm, a spin on carbon (SOC), or high temperature SOC layer, or amorphous carbon layer obtained by chemical vapor deposition, layer 140, of 200-400 nm, and a substrate 150, respectively. In such stack, we have to our surprise found that the functional layer decreases the required dose to pattern by 15-30%. Such improvement is advantageous as the dose on the substrate is controlled by exposure time. Thus, a decreased dose means a shorter time for the exposure step, which in turns mean improved efficiency and higher throughput. Additionally, decreased dose may affect positively to necessary maintenance procedures increasing the economical benefit obtained by the use of such functional layer.

According to an embodiment, the present technology relates to a composition suitable for formation of a siloxane layer on a substrate, said composition comprising a siloxane polymer containing SiO moieties, a plurality of sites distributed along the polymer containing a first polyaromatic portion containing both nitrogen and sulfur atoms with a dihedral angle of <165° between two benzene rings and with a C—S—C bond angle of <110°, and an intermediate aromatic and non-aromatic portion, wherein the polymer has a molecular weight of from 500 to 50,000 g/mol, and the composition preferably further comprises an acid and/or base and a solvent.

According to an embodiment, a polymer composition is provided which is suitable for the production of a coating formulation that can be cast on substrates and in which the polymer in the formulation yields a coating, which represented by a general formula (I)

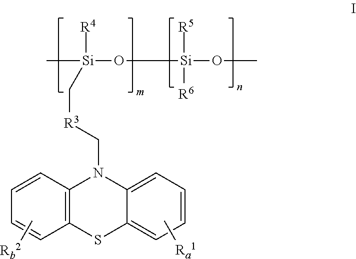

In Formula I,
Rₐ¹ and R_{b}² stand for halogen or hydrocarbyl radical that can be independently selected from optionally functionalized linear, branched or cyclic alkyl groups, optionally functionalized aromatic or polyaromatic groups;
R³ stands for a bridging hydrocarbyl radical that can be independently selected from optionally functionalized linear, branched or cyclic, bivalent, saturated or unsaturated hydrocarbyl radicals, such as an optionally functionalized linear, branched or cyclic alkylene, alkenylene or alkynylene group; and optionally functionalized bivalent aromatic or polyaromatic groups;
R⁴ stand for hydrogen, hydroxyl, halogen, alkoxy or acyloxy or a hydrocarbyl radical, wherein the hydrocarbyl radical can be independently selected from optionally functionalized linear, branched or cyclic alkyl groups, optionally functionalized aromatic or polyaromatic groups, or an optionally substituted polyaromatic hydrocarbyl radical having both nitrogen and sulfur atoms;
R⁵ and R⁶ stand for hydrogen, hydroxyl, halogen, alkoxy or acyloxy or a hydrocarbyl radical, wherein the hydrocarbyl radical can be independently selected from optionally functionalized linear, branched or cyclic alkyl groups, optionally functionalized aromatic or polyaromatic groups;
a and b are independently selected from integers having a value in the range from 0 to 4; and
m and n are independently selected from integers having a value in the range from 1 to 1000.

The above composition is obtained by hydrolyzing a first monomeric silicon compound having a substituent that contains an aromatic structure containing both sulfur and nitrogen atoms and least one hydrolysable group attached to the silicon (“Precursor A”) with optionally one or more monomeric silicon compounds having at least one hydrolysable group i.e. “Precursor B”.

The ratio of the precursors used in the present invention can vary.

In one embodiment, precursor A is used in in an amount of 1-100 mole %, such as 20 to 90 mole-%, for example 30 to 80 mole-% or 40 to 70 mole-%. Precursor B can be used in 0-99 mole %, such as 10 to 80 mole-%, for example 20 to 70 mole-% or 30 to 60 mole-%. The siloxane composition can be obtained by carrying out the hydrolysis and condensation in the same reaction vessel or separately in specified portions or each precursor independently.

The present invention is particularly well suited for the production of compositions comprising a poly(organosiloxane) obtained by hydrolyzing a first silicon compound having the general formula II or precursor A below

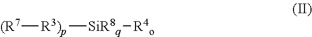

In the composition,
R⁷ stands for an optionally substituted polyaromatic hydrocarbyl radical having both nitrogen and sulfur atoms;
R⁸ stands for an alkoxy group, an acyloxy group, or a halogen group;
R³ and R⁴ have the same meaning as above in Formula I;
p and q are independently integers of 1 to 3,
o is an integer of 1 or 2, and
the total value of p+q+o does not exceed 4.

When substituted, R⁷ typically bears substituents R¹ₐ and R²_{b} in which R¹, R², a and b have the same meaning as in Formula I.

In one embodiment, the compounds of Formula II have a generally butterfly-like shape, substituted or unsubstituted phenothiazines. In the phenothiazines, the central C4SN ring is folded.

The substituents can be selected from the group of halo, alkyl, alkoxy, cyano, oxo, thio, alkylsulphanyl, sulphinyl, acyl, and perfluorinated alkyl groups.

The residues R⁷ of formula (II) can be derived from the following structures, which are given as non-limiting Examples:

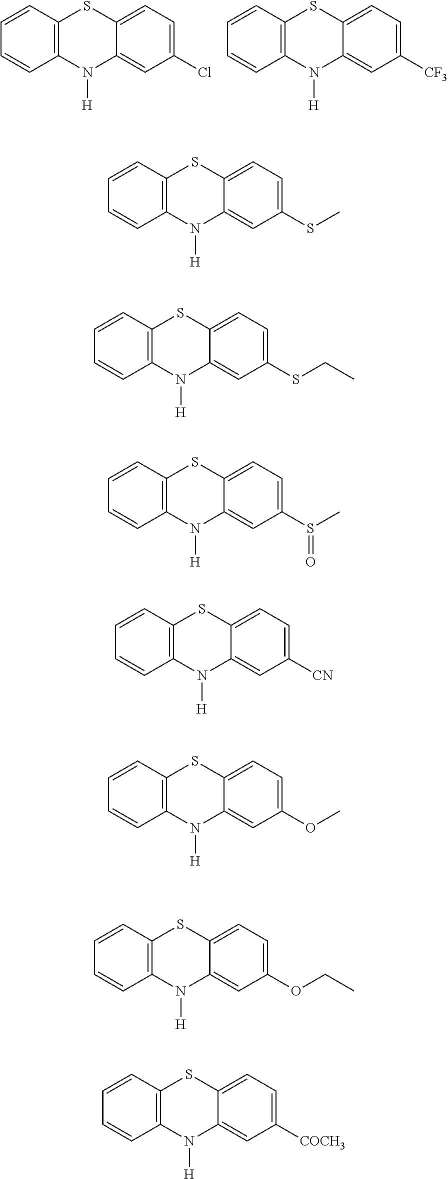

In one embodiment, the residue R³ of Formula (II) is derived from aliphatic or aromatic or cyclic or heterocyclic vinyl or alkynyl precursor compounds, such as the following:

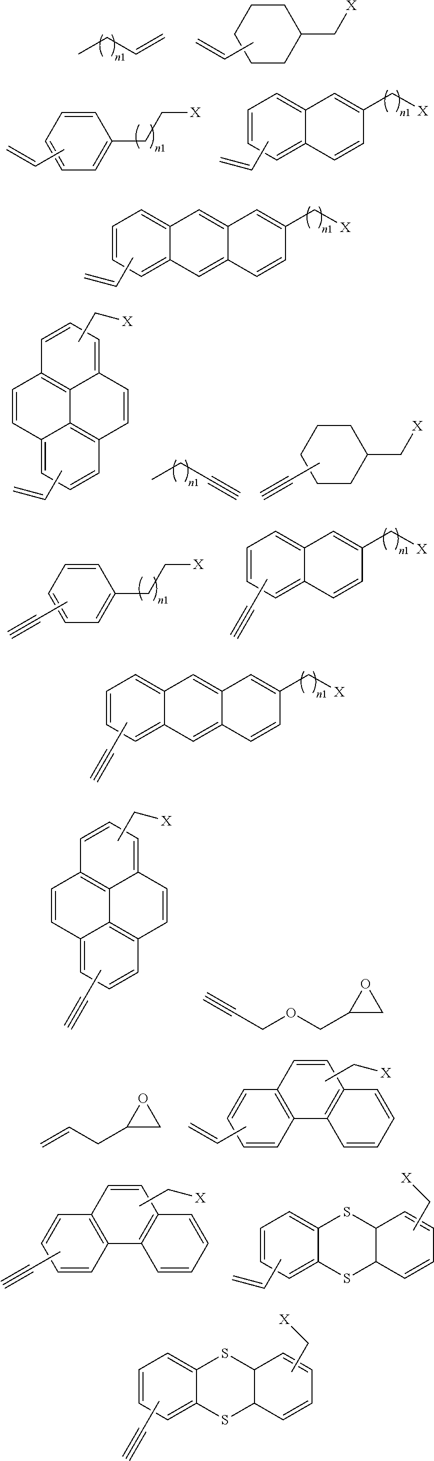

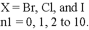

The present invention also relates to the compositions comprising a copoly(organosiloxane) obtained by hydrolyzing the first silicon compound having the general formula II, with a precursor B having the general formula III

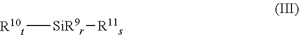

wherein
R⁹ stands for an alkoxy group, an acyloxy group, or a halogen group,
R¹⁰ and R¹¹ are independently selected from alkyl, aryl, aralkyl, halogenated alkyl, halogenated aryl, halogenated aralkyl, alkenyl, organic having one or more epoxy, mercapto, alkoxyaryl, acyloxyaryl. Isocyanurate, hydroxy, cyclic amino, cyano groups, and combinations thereof; or R¹⁰ and R¹¹ are independently selected from alkoxy groups, acyloxy groups, and halogen groups
t is an integer of 0 to 3,
r is an integer of 1 to 4, and
s is an integer of 0 to 3, and
wherein the total value of t+r+s may not exceed 4.

Specific examples of precursor B having formula (III) include but are not limited to tetramethoxysilane, tetrachlorosilane, tetraacetoxysilane, tetraethoxysilane, tetra-n-propoxysilane, tetraisopropoxysilane, tetra-n-butoxysilane, methyltrimethoxysilane, methyltriethoxysilane, methyltrichlorosilane, methyltriacetoxysilane, methyltripropoxysilane, methyltributoxysilane, methyltriphenoxysilane, methyltribenzyloxysilane, ethyltrimethoxysilane, ethyltriethoxysilane, phenyltrimethoxysilane, phenyltrichlorosilane, phenyltriacetoxysilane, phenyltriethoxysilane, γ-mercaptopropyltrimethoxysilane, γ-mercaptopropyltriethoxysilane, β-cyanoethyltriethoxysilane, dimethyldimethoxysilane, phenylmethyldimethoxysilane, dimethyldiethoxysilane, phenylmethyldiethoxysilane, dimethyldiacetoxysilane, γ-mercaptopropylmethyldimethoxysilane, γ-mercaptomethyldiethoxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, and phenylsulfonylaminopropyltriethoxysilane, vinyltrimethoxysilane, vinyltrichlorosilane, vinyltriacetoxysilane, vinyltriethoxysilane, methylvinyldimethoxysilane, methylvinyldiethoxysilane, γ-methacryloxypropyltrimethoxysilane, γ-methacryloxypropylmethyldimethoxysilane, γ-methacryloxypropylmethyldiethoxysilane, (methacryloxymethyl)methyldiethoxysilane, (methacryloxymethyl)methyldimethoxysilane, methacryloxymethyltriethoxysilane, methacryloxymethyltrimethoxysilane, methacryloxypropyltrichlorosilane, methacryloxypropyltriethoxysilane, methacryloxypropyltriisopropoxysilane, γ-chloropropyltrimethoxysilane, γ-chloropropyltriethoxysilane, γ-chloropropyltriacetoxysilane, chloromethyltrimethoxysilane, chloromethyltriethoxysilane, γ-chloropropylmethyldimethoxysilane, γ-chloropropylmethyldiethoxysilane, 3,3,3-trifluoropropyltrimethoxysilane, 4-acetoxyphenylethyltrimethoxysilane, 4-acetoxyphenylethyltriethoxysilane 4-(acetoxyphenylethyl)methyldichlorosilane, 4-(acetoxyphenylethyl)methyldimethoxysilane, 4-(acetoxyphenylethyl)methyldiethoxysilane, triethoxysilylpropylcarbamate, triethoxysilylpropylmaleamic acid, N-(3-triethoxysilylpropyl)-4-hydroxybutyramide, N-(3-triethoxysilylpropyl)gluconamide, (3-triethoxysilyl)propylsuccinic anhydride, ureidopropyltriethoxysilane, ureidopropyltrimethoxysilane, 3-hydroxy-3,3-bis(trifluoromethyl)propyl triethoxysilane, 4-(methoxymethoxy)trimethoxysilylbenzene and 6-(methoxymethoxy)-2-(trimethoxysilyl)-naphthalene.

According to one embodiment, the hydrolysis and polymerization of the novel butterfly shape aromatic compound containing sulfur and nitrogen atoms of dihedral angle of <165° between two benzene rings with a C—S—C bond angle of <110° of the formula (II) either alone or in a variety of molar percentages with other silicon containing monomers is carried out completely without solvents.

In another embodiment, the hydrolysis and polymerization of the novel aromatic compound containing sulfur and nitrogen atoms of dihedral angle of <165° between two benzene rings with C—S—C bond angle of <110° of the formula (II) either alone or in a variety of molar percentages with other silicon containing monomers is carried out in organic solvents, such as in alcohols, esters, ketones and ethers, or mixtures thereof. Specific, suitable solvents are acetone, ethyl methyl ketone, methanol, ethanol, isopropanol, butanol, methyl acetate, ethyl acetate, propyl acetate, butyl acetate and tetrahydrofuran (THF). Particularly suitable solvents are alcohols, ketones and ethers and mixtures thereof.

Hydrolysis of the monomers can be carried out in an acid or base solution comprising a molar concentration of from 0.0001 M to 1 M of the acid or base.

In one embodiment, the acid solution used during hydrolysis comprises an inorganic or organic acid or a mixture thereof. Examples of inorganic acids include nitric acid, sulfuric acid, hydrochloric acid, hydriodic acid, hydrobromic acid, hydrofluoric acid, boric acid, perchloric acid, carbonic acid and phosphoric acid and mixtures thereof. Preferably, nitric acid or hydrochloric acid is used due to their low boiling point, which make purification of product simple. In another option, organic acids are used. As examples of organic acids or acidic compounds the following can be mentioned: carboxylic acid, sulfonic acid, alcohol, thiol, enol, and phenol groups. Specific examples include the following: methanesulfonic acid, acetic acid, ethanesulfonic acid, toluenesulfonic acid, formic acid, and oxalic acid and mixtures thereof.

In one embodiment, the basic (alkaline) solution used during hydrolysis comprises an inorganic or organic base. Typical inorganic bases and metal hydroxides, carbonates, bicarbonates and other salts that yield an alkaline water solution. Examples of such materials are sodium hydroxide, potassium hydroxide, cesium hydroxide, calcium hydroxide, sodium carbonate, and sodium bicarbonate. Organic bases on the other hand comprise a larger group consisting of metal salts of organic acids (such as sodium acetate, potassium acetate, sodium acrylate, sodium methacrylate, sodium benzoate), linear branched or cyclic alkylamines (such as diaminoethane, purtescine, cadaverine, triethylamine, butylamine, dibutylamine, tributylamine, piperidine) amidines and guanidines (such as 8-diazabicyclo(5.4.0)undec-7-ene, 1,1,3,3-tetramethylguanidine, 1,5,7-triazabicyclo[4.4.0]-dec-5-ene), phosphazanes (such as Py-t-Bu, P₂-t-Bu, P₄-t-Bu), and quarternary ammonium compounds (such as tetramethylammonium hydroxide, tetraethylammonium hydroxide, tetrabutylammonium hydroxide).

The temperature of the reaction mixture during the hydrolysis and condensation process can be varied in the range from −30 to 170° C. Lower reaction temperatures generally provide improved control of the reaction, whereas high temperatures will increase the reaction rate. In one embodiment, the reaction time is 1 to 48 h and the temperature is in the range from 0 to 100° C. A reaction time of 2 to 24 h is preferred.

Using appropriate conditions, the method according to the present invention yields a partially cross-linked sulfur and nitrogen containing organosiloxane polymer in an organic solvent system, said polymer having a molecular weight (M_{w}) of about 5,000 to 100,000 g/mol, in particular about 1,000 to 10000 g/mol, measured against polystyrene standards.

In another embodiment the solvent in which hydrolysis and polymerization is carried out (the “first solvent”), is after polymerization changed for another solvent or a mixture of solvents (the “second solvent”). Typically, the second solvent is selected such that it provides the material with better coating performance and product storage properties. In one embodiment, this is achieved through stabilization.

An embodiment provides a composition comprising a poly(organosiloxane) resin in liquid phase, comprising a poly(organosiloxane), as described herein, in the liquid phase formed by at least one organic solvent for the poly(organosiloxane) resin, optionally in mixture with water. The composition can be formulated for use in a method of a coating a substrate by casting.

In one embodiment, the organic liquid preferably has a flash point of at least 10° C. and a vapor pressure at 20° C. of less than about 10 kPa.

Examples of stabilizing organic solvent system are represented by one or more organic ethers optionally in mixture with other co-solvent or co-solvents.

In one embodiment, the organic ether is a linear, branched or cyclic ether comprising generally 4 to 26 carbon atoms and optionally other functional groups, such as hydroxyl groups. Particularly suitable examples are five and six membered cyclic ethers, which optionally bear substituents on the ring, and ethers, such as (C1-20) alkanediol (C1-6) alkyl ethers. Examples of said alkanediol alkyl ethers are propylene glycol monomethyl ether, propylene glycol dimethyl ether, propylene glycol n-butyl ether, dipropylene glycol monomethyl ether, dipropylene glycol. dimethyl ether, dipropyleneglycol n-butyl ether, tripropylene glycol monomethyl ether and mixtures thereof.

Particularly preferred examples of the present ethers are methyl tetrahydrofurfuryl ether, tetrahydrofurfuryl alcohol, propylene glycol n-propyl ether, dipropylene glycol dimethyl ether, propylene glycol n-methyl ether, propylene glycol n-ethyl ether (PGEE) and mixtures thereof. The stabilizing solvent system consists of a solvent comprising of the ether of this kind alone, or of a mixture-of such ether with a typical reaction medium of the hydrolyzation or other solvents such as propylene glycol monomethyl ether acetate (PGMEA). The proportion of the ether is, in such a case, about 10 to 90 wt %, in particular about 20 to 80 wt %, such as 25 to 75 wt %, of the total amount of the solvent.

In one embodiment, the liquid phase of the present compositions comprises a solvent selected from PGMEA, PGEE, THF and mixtures thereof.

The solid content of a formulation comprising, consisting of or consisting essentially of solvents and resin material is in the range of 0.1% to no more than 50%. Most preferably the solid content is in the range of 0.5% to 10%, such as 1 to 4%. The polymer solution has typically a viscosity from about 0.5 centipoises (cP) to about 150 cP, such as 1 to 100 cP, e.g. 5 to 75 cP.

The solid content (or polymer content) is used to adjust the resultant film thickness during the coating process.

In one embodiment, the present compositions exhibit a silicon content higher than 20%, more preferably higher than 25%, most preferably more than 30%, calculated from the dry weight of the composition.

To improve the coating performance in terms of coating uniformity, different surfactants, such as one or more silicone or fluoro surfactants or combinations thereof, can be used for example for lowering the surface tension of the poly(organosiloxane) or polysilsesquioxane formulation coating. The use of such surfactants may improve coating quality. The amount of surfactant is in a range of 0.001% to no more than 10% by mass compared to silanol-containing polysilsesquioxane amount.

In one embodiment, a compound selected from photo or thermally labile catalysts or compounds is added to formulation mixture to enhance the cross-linking of the polysiloxane films. The amount of thermo or photo labile compounds into the formulation in the range of 0.1 to 20%, most preferably 0.2-10%, e.g. 0.5 to 7.5%, corresponds to the solid content of the polysiloxane.

The present polysilsesquioxanes or compositions thereof can be used for spin coating of substrates, such as silicon substrates, for example silicon wafers. By such layers, the molar absorptivity can be increased.

The present butterfly shape nitrogen and sulfur containing materials can used as additives to adjust, i.e. to “tune”, the polymer film thickness, index of refraction (n), molar absorptivity (k), and contact angle (CA) of corresponding siloxane-based photoresist polymer.

In one embodiment, by coating a substrate, such as a silicon wafer, with a layer of this kind, the absorption coefficient (k) at 248 nm increased up to 0.55 upon introduction of the present sulfur and nitrogen containing precursor from 1 to 100 mol percent compared to that (0.02) obtained by a corresponding non-modified polysilsesquioxane or composition thereof.

The polymer composition of Formula (I) comprising at least one sulfur and nitrogen containing butterfly shape aromatic group/s with dihedral angle of <165° between two benzene rings with C—S—C bond angle of <110° that strongly absorb light in the range of 200 to 600 nm wavelength exhibits an index of refraction between 1.3 to 1.7 depending on the amount of sulfur and nitrogen containing aromatic monomer for example of Formula (IV) in the polymer composition. The polymer composition Formula (I) spin-coated on silicon wafer show increment in refractive index at 248 nm wavelength with increase in amount of monomer of for example Formula (IV) in siloxane-based polymer composition.

The invention also pertains to a method of preparing silicon-based precursors according to formula (II).

In one embodiment, the compound of formula (II) is prepared by the two-step method illustrated in Scheme 1.

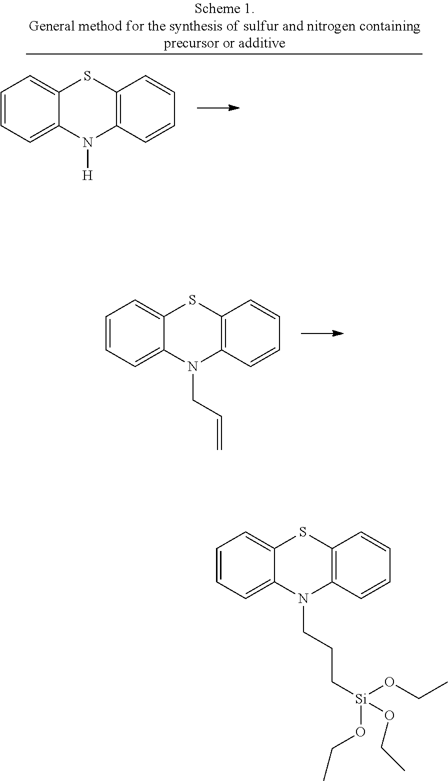 [SMILES: c1ccc2c(c1)Nc1ccccc1S2 ; C=CCN1c2ccccc2Sc2ccccc21 ; CCO[Si](CCCN1c2ccccc2Sc2ccccc21)(OCC)OCC]

In the above method, an aromatic compound, in particular exhibiting a butterfly shape, containing sulfur and nitrogen heteroatoms is dissolved in a suitable solvent, and then an n-alkylation reaction is carried out in the presence of a suitable inorganic/organic base, using a reactant that contains a halogen atom and an unsaturated carbon-carbon bond, such as allyl bromide as shown in scheme 1.

The reaction can be carried out at variable temperatures, preferably between 25 and 150° C., more preferably between 3° and 120° C., and most preferably between 4° and 100° C. or 50 to 100° C. The reaction time can be varied until the reaction completion has been determined by means of thin layer, gas or liquid chromatography. After this, the intermediate product may be obtained by purification by column chromatography, crystallization, sublimation or distillation.

The crude intermediate or its purified form is introduced to a silicon precursor containing a Si—H bond, such as triethoxysilane optionally a solvent and a catalytic hydrosilylation reaction is carried out where the Si—H is added over the unsaturated carbon-carbon. An example of such catalyst is a platinum complex with 1,3-divinyltetramethyldisiloxane. Again, the reaction can be carried out at variable temperatures, preferably between 25 and 150° C., more preferably between 3° and 120° C., and most preferably between 4° and 100° C. or 50 to 100° C. The reaction time can be varied until the reaction completion has been determined by means of thin layer, gas or liquid chromatography.

Finally, optional solvents and excess of reagents are removed prior to final purification of the desired compound.

The above method can also be utilized to achieve any polycyclic aromatic compound/s with any substituents linked halogenated hydrocarbon that contains either vinyl or alkynyl double bond via n-alkylation. The respective compound is further reacted with Si—H containing precursors or compounds to achieve hydrosilylated desired aromatics.

Examples of particularly preferred compounds corresponds to formula (IV) are as follows:

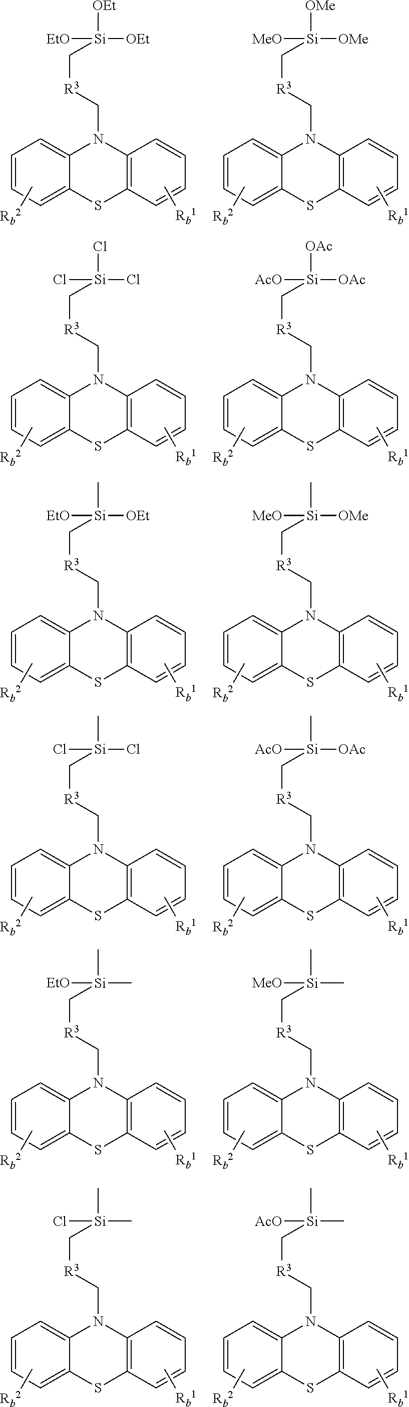

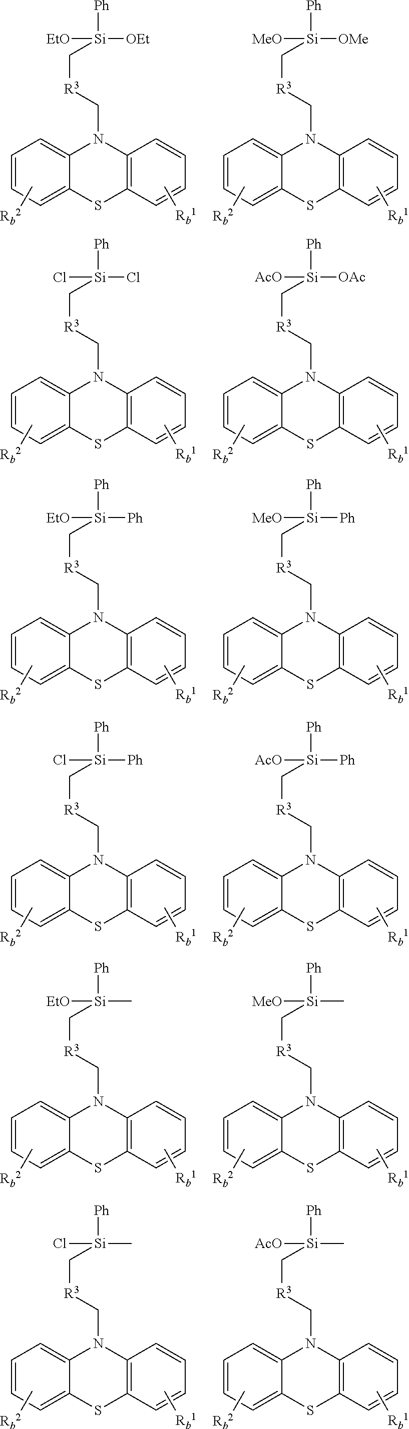

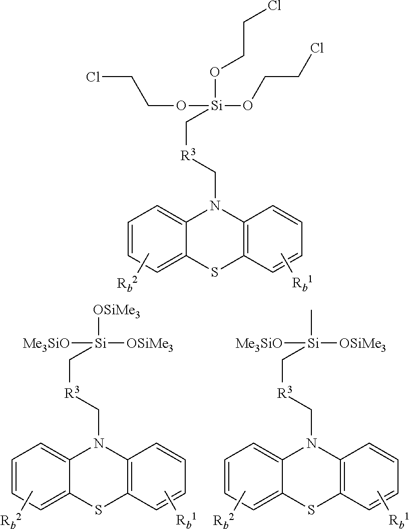

In the above formulas,
Rₐ¹ and R_{b}² and R³ have the same meaning as above in formula I.

Upon incorporation of the novel aromatic compound containing sulfur and nitrogen atoms in a polymer composition, high refractive index (n) coatings can be obtained. Surprisingly, in an embodiment (Example 1), a homopolymer prepared from a sulfur and nitrogen containing precursor exhibited as high as 1.66 refractive index at 633 nm while the material of a comparative example showed n of 1.65 n at 633 nm. Therefore, the present invention can be utilized to further increase the refractive index.

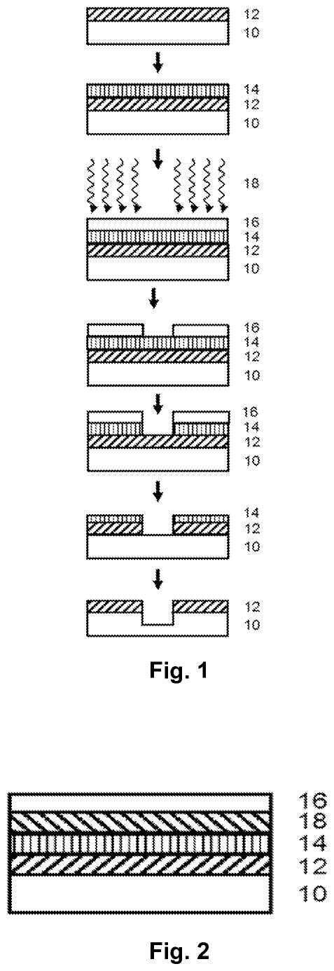

FIG. 1 shows schematically a typical lithographic process comprising or consisting of a subsequent deposition of a carbon-based underlayer material 12, a silicon-based middle layer 14 and a radiation sensitive resist layer 16. In this process, underlayer coatings 12 and 14 are sequentially coated and baked, prior to deposition of the following coating layer. After this, the radiation sensitive resist layer is selectively irradiated e.g. through a mask containing the desired patterns. The patterning is then developed and subsequently the obtained pattern is transferred by an etch process using fluorine chemistries either in the gas or liquid phase to underlayer 14. Then the pattern is transferred by a gas phase plasma enhanced etch process to the carbon-based underlayer 12. Of typical importance in this step is the etch selectivity between layers 12 and 14. Typically an improved etch selectivity is obtained by silicon-based middle layers exhibiting high silicon and low carbon content. Finally, the obtained pattern is transferred to the substrate. The resist and the underlayers are typically removed upon completion of the process.

A typical tri-layer lithographic process of coating different layers is presented in FIG. 1.

Additionally, organic bottom anti-reflective (OBARC) layer 18 is utilized in four-layer lithographic process to tune refractive index (n) and extinction coefficient (k) and increases further steps in device construction shown in FIG. 2.

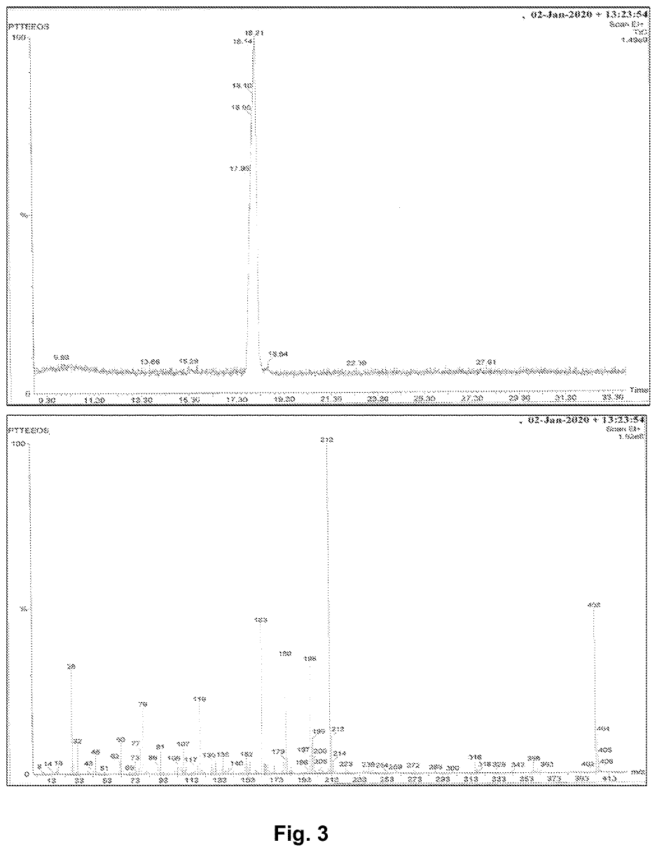

FIG. 3 shows mass spectra of newly made monomer and corresponding fragmentation pattern.

FIG. 4 shows a lithographic process utilizing a functional layer in a lithographic process. On a substrate 150, a layer 140 based on a spin on carbon (SOC) or an α-carbon by chemical vapor deposition is deposited with a thickness of 200-400 nm. Then, a high silicon-based middle layer Si-BARC or silicon oxynitride or metal oxide layer 130 of thickness 20-50 nm is deposited on layer 140. After this, the functional coating 120 based on present invention is deposited with a layer thickness of, for example, 5-10 nm. Finally, a radiation/light (e.g. 13.5 nm, 193 nm, 248 nm 365 nm, but not limited to these) or electron beam radiation sensitive photoresist layer 110 of 40-50 nm is deposited on layer 120.

In the device fabrication steps, the photoresist layer 110 is irradiated with the selected wavelength or with electron beam, respectively, through a mask of predetermined pattern(s). The patterning is then developed and subsequently the obtained pattern is transferred by an etch process using fluorine chemistries either in the gas or liquid phase to subsequent functional layer 120 presented in here and high silicon content Si-BARC layer, an improved etch selectivity is obtained by silicon-based middle layers exhibiting high silicon and low carbon content. Finally, the obtained pattern is transferred to the substrate. The resist and the underlayers are typically removed upon completion of the process. The use of the instant functional layer has been found to decrease the required dose by 15-30% in the patterning of line and space structures with a 32 nm half pitch, as shown in example 14.

It is worth to note that upon utilization of polysiloxane compositions comprising the present sulfur and nitrogen containing monomer(s) provides the benefit over four-layer architecture by tuning n and k parameters without utilization of OBARC layer and thus, simplifies lithographic process.

Thus, the present invention finds use not only as an anti-reflective coating composition due to high refractive index but also as polysiloxane compositions that can be utilized in deep ultraviolet ArF/KrF lithography to tune the n and k parameters. Additionally, by introducing a monomer of the newly designed kind, typically having a butterfly shape, n and k parameters and contact angle of polymeric compositions can be significantly tuned, discussed above.

In one embodiment, the coating materials is sensitive to selected radiation, such as extreme ultraviolet light, ultraviolet light and/or electron beams.

Furthermore, in one embodiment, the precursor solutions are formulated to be stable with a predetermined shelf life for commercial distribution.

The formation of integrated electronic devices and the like generally involves the patterning of the materials to form individual elements or components within the structures. This patterning can involve different compositions covering selected portions of stacked layers that interface with each other vertically and/or horizontally to induce desired functionality.

The various materials can comprise semiconductors, which can have selected dopants, dielectrics, electrical conductors and/or other types of materials. To form high resolution patterns, radiation sensitive organic compositions can be used to introduce patterns, and the compositions can be referred to as resists since portions of the composition are processed to be resistant to development/etching such that selective material removal can be used to introduce a selected pattern.

The present technology also provides for underlayer coatings for, e.g., semiconductors and components thereof.

In one embodiment, a resist underlayer coating for lithography comprises
a silane, at least one among a hydrolyzable organosilane, a hydrolysis product thereof, and a hydrolysis-condensation product thereof, wherein
the silane includes the silane compound of Formula (I) alone or as a copolymer with one or more silane compound of Formula (II).

In one embodiment, the resist underlayer film is obtained by applying a poly(organosiloxane) composition onto a semiconductor substrate, and by baking the composition.

In one embodiment, the present functional layer coatings are applied to form lithographic stacks including at least the following layers:
a Photoresist (organic, inorganic, hybrid, metal oxide) layer of 40-50 nm;
a Functional layer of novel polymer composition presented in the present technology of, for example, 5-10 nm;
a Si-BARC or silicon oxynitride or metal oxide layer of 20-50 nm; and
a SOC included both low and high temperature spin-on carbon 200-360° C. or a chemical vapor deposition (CVD) α-carbon layer of 200-400 nm and finally a
substrate.

Metal oxides may include metal oxides typically used in photoresists, such as Group 4 metal oxides.

One further embodiment provides a method of producing a semiconductor device. The method comprises generally the steps of
applying a resist underlayer film forming poly(organosiloxane) composition as described herein onto a semiconductor substrate;
baking the composition to form a resist underlayer film;
applying a composition for a resist onto the resist underlayer film to form a resist film;
exposing the resist film to light;
developing the resist film after the exposing to obtain a patterned resist film;
etching the resist underlayer film according to a pattern of the patterned resist film; and
processing the semiconductor substrate according to a pattern of the resist film and the resist underlayer film.

An embodiment for producing a semiconductor device comprises
forming an organic underlayer film on a semiconductor substrate;
applying the resist underlayer film forming poly(organosiloxane) composition as described herein onto the organic underlayer film;
baking the composition to form a resist underlayer film;
optionally, forming an organic bottom anti-reflective film on the poly(organosiloxane) resist underlayer
applying a composition for a resist onto the resist underlayer film to form a resist film;
exposing the resist film to light;
developing the resist film after the exposing to obtain a patterned resist film;
etching the resist underlayer film according to a pattern of the patterned resist film;
etching the organic underlayer film according to a pattern of the pattered resist underlayer film; and
processing the semiconductor substrate according to a pattern of the patterned organic underlayer film.

The present technology provides for the forming of ARC film by application of a composition as described above for forming a resist underlayer film onto a semiconductor substrate and baking the composition.

In one embodiment, there is provided a method for producing a semiconductor device, comprising:
applying a resist underlayer film or several underlayer films onto a semiconductor substrate and baking the composition to form one or more resist underlayer films;
applying a composition according to claim 1 as an ARC onto one or more resist underlayer films to form a resist film;
exposing the resist film to light;
after the light exposure, developing the resist film to form a resist pattern;
etching the resist underlayer film using the resist pattern; and
fabricating the semiconductor substrate using the resist film thus patterned and the resist underlayer film thus patterned.

In one embodiment, there is provided a method for producing a semiconductor device, comprising:
forming an organic underlayer film on a semiconductor substrate;
applying the composition for forming a resist film onto the organic underlayer film and baking the composition to form a resist film;
exposing the resist film to light;
after the light exposure, developing the resist film to form a resist pattern;
etching the resist underlayer film using the resist pattern;
etching the organic underlayer film using the resist underlayer film thus patterned; and
fabricating the semiconductor substrate using the organic underlayer film thus patterned.

The technology also provides for a method of producing a semiconductor device, the method comprising:
applying a resist underlayer film or several underlayer films onto a semiconductor substrate and baking the composition to form one or more resist underlayer films;
applying a composition according to claim 1 as an ARC onto one or more resist underlayer films to form a resist film;
exposing the resist film to light;
after the light exposure, developing the resist film to form a resist pattern;
etching the resist underlayer film using the resist pattern; and
fabricating the semiconductor substrate using the resist film thus patterned and the resist underlayer film thus patterned.

Further, a method for producing a semiconductor device comprises the steps of
forming an organic underlayer film on a semiconductor substrate;
applying the composition for forming a resist film onto the organic underlayer film and baking the composition to form a resist film;
exposing the resist film to light;
after the light exposure, developing the resist film to form a resist pattern;
etching the resist underlayer film using the resist pattern;
etching the organic underlayer film using the resist underlayer film thus patterned; and
fabricating the semiconductor substrate using the organic underlayer film thus patterned.

The present solutions can be used for cast coatings on semiconductor substrates as bottom anti-reflective coating (BARC) before the coating of photoresist layer. In particularly, the newly made nitrogen and sulfur containing butterfly shape compound with dihedral angle of <165° between two benzene rings with C—S—C bond angle of <110° and its composition upon application as BARC effectively address the photolithographic limitations e.g., substrate reflectivity, swing effect, and reflective notching.

It is also worth to note that the nanoparticle free high refractive index composition presented in this work make it particularly attractive and provide an efficient solution to storage stability, high optical loss, and poor processability. Moreover, upon addition of newly made sulfur and nitrogen containing compound in underlayer formulation significantly tunes the long-term stability of polymer composition via enhancement/tuning in water contact angle of parent material and thus makes it hydrophobic in nature. More importantly due to its organic-inorganic hybrid nature, the polysiloxane composition in one embodiment used for providing resistance to oxygen plasma and hence high etch selectivity.

The present solution gives as high as 1.66 refractive index at 633 nm without use of external nanoparticles or additives. Additionally, the use of coatings comprising a sulfur and nitrogen containing butterfly shape compound with dihedral angle of <165° between two benzene rings with C—S—C bond angle of <110° polysiloxane, photoacid generator, photosensitizers depending upon requirement for specific lithographic wavelengths, high boiling organic solvents, additives, and surfactants.

Surprisingly it has been found that, in some embodiments, upon introduction of the present monomers in polysiloxane compositions the refractive index of the material can be significantly enhanced up to 1.66 at a wavelength of 633 nm. A predetermined refractive index can be achieved by varying the proportion of the present monomers in the polysiloxane composition. The amount of monomer, compared to that of the other silane monomers, can vary from 1 to 100 mole percent to achieve refractive indexes in the range from 1.42 to 1.66 at 633 nm wavelength.

It is worth noting that the present solution typically shows a significant increase in refractive index in the range from 1.34 to 1.72 at 193 nm (ArF) and from 1.49 to 1.99 at 248 nm (KrF) deep ultraviolet lithographic wavelengths, respectively.

In one embodiment, upon addition of present precursors as additives in polysiloxane composition the water contact angle of parent polymer composition was increased from 58 to 62 degrees. Additionally, as an additive the present material stabilizes the properties (contact angle, thickness, refractive index, and molecular weight) of parent polymer up to 42 days that indicates the potential of the material to improve the hydrophobicity of polymer compositions and thus leading to improved stability of underlayer polymer compositions.

Thus, generally, by using a poly(organosiloxane) as described herein as an additive in a siloxane polymer composition it is possible to obtain a film having a thickness of 30 to 60 nm, especially 35 nm, and exhibiting an essentially constant molecular weight and contact angle over a time period of 42 days at room temperature.

The polymer composition mentioned in formula (I) comprises at least one sulfur and nitrogen containing group, such as a butterfly shape aromatic group with dihedral angle of <165° between two benzene rings with C—S—C bond angle of <110°, that strongly absorb light in the range of 200 to 400 nm wavelength. In embodiments the polymer exhibited an index of refraction between 1.3 to 1.7 depending on the amount of the aromatic monomer of formula (IV), which contains sulfur and nitrogen, in the polymer composition.

The polymer composition of the formula (I), spin-coated on silicon wafer, showed increment in refractive index at 248 nm wavelength when the amount of monomer of the formula (IV) in siloxane-based polymer composition was increased.

In addition, in the polymer composition of the formula (I), spin-coated on silicon wafer, the molar absorptivity (k) increased with respect to the mole percent of novel monomer (IV) contribution in polymer composition.

The polymer composition of the formula (I) can be used to achieve high-refractive index material and in application of ARC in photolithography for either before or after the photoresist in order to prevent standing wave and thin-film interference.

The following non-limiting examples illustrate embodiments of the present technology.

### Synthesis of precursor 10-(3-(triethoxysilyl) propyl)-10H-phenothiazine (‘PTTEOS’)

Synthesis of the silicon precursor (‘PTTEOS’) having an aromatic substituent containing both nitrogen and sulfur atoms was carried out in a 500 ml round bottom flask. Phenothiazine (50.0 g, 0.250 mol), K₂CO₃ (52.0 g, 0.370 mol) and acetone (200 ml) were added to the round bottom flask equipped with a magnetic stirrer and a reflux condenser. Upon complete dissolution of phenothiazine, the reaction was brought to reflux and allowed to proceed for 30 min. Then, allyl bromide (48.6 g, 0.400 mol) of was added and the reaction was allowed to proceed for 24 h. The completion of the reaction confirmed by TLC.

The reaction mixture was then allowed to cool and filtered. Then, acetone and excess allyl bromide was removed under reduced pressure. The obtained solution was diluted with THF (200 ml) and Karstedt's catalyst was added into the reaction mixture. The reaction mixture was brought to reflux and triethoxysilane (62.0 g) was added and the reaction was allowed to proceed for 24 h. The solvent and excess of triethoxysilane was evaporated under reduced pressure. The obtained residue was distilled (155° C., 0.01 mbar) and 65.0 g of product was collected and confirmed by Gas Chromatography Mass Spectroscopy (FIG. 4).

### Example 1

A homopolymer of the obtained precursor (‘PTTEOS’) was prepared in a 100 ml round bottom flask. The precursor (10.0 g, 0.024 mol), 0.01M HCl (2.0 g), and acetone (10.0 g) were added. The reaction mixture was brought to reflux and allowed to proceed for 4 h. Then, the reaction was allowed to cool to room temperature and PGMEA (50.0 g) was added. Acetone and hydrolysis products were removed under reduced pressure yielding a formulation having a solid content of 35%. Finally, the obtained polymer solution was filtered with 0.2-micron filter and characterized by Gel permeation chromatography (GPC) afforded M_{w}/Mₙ of 1556/1163. The 1% solution of polymer was made in PGMEA and spin-coated on silicon wafer to measure the refractive index and molar absorptivity of polymer at different lithographic wavelengths (193 & 248 nm), as known for those familiar with art.

### Example 2

Following the procedure described in Example 1, PTTEOS (10.0 g, 0.024 mol), glycidoxypropyltrimethoxysilane (GPTMOS, 1.0 g, 0.004 mol), 0.01M HCl (2.0 g), and acetone (11.0 g) were used. The obtained polymer solution was filtered with 0.2-micron filter and characterized by Gel permeation chromatography (GPC) afforded M_{w}/Mₙ of 2518/2234.

### Comparative Example 1

Following the procedure described in Example 1, GPTMOS (108.0 g, 0.450 mol), 9-phenanthrenyltriethoxysilane (EtoPhen, 612.0 g, 1.790 mol), 0.01M HNO₃ (244.0 g), acetone (540.0 g, 9.290 mol), and PGMEA (1200.0 g) were used. The obtained polymer solution was filtered with 0.2-micron filter and characterized by Gel permeation chromatography (GPC) afforded M_{w}/Mₙ of 1294/1703.

### Example 3

Following the procedure described in Example 1, PTTEOS (5.0 g, 0.024 mol), Tetraethoxysilane, (TEOS, 6.0 g, 0.029 mol), Methyltriethoxysilane, (MTEOS, 5.6 g, 0 031 mol), 0.01M HCl (6.7 g), and acetone (23.4 g) were used. The obtained polymer solution was filtered with 0.2-micron filter and characterized by Gel permeation chromatography (GPC) afforded M_{w}/Mₙ of 1517/1074.

### Example 4

Following the procedure described in Example 1, PTTEOS (3.0 g, 0.007 mol), TEOS (62.03 g, 0.290 mol), MTEOS (57.0 g, 0.320 mol), EtoPhen (40.5 g, 0.110 mol), 0.01M HCl (68.7 g), and acetone (231.3 g) were added. The obtained polymer solution was filtered with 0.2-micron filter and characterized by Gel permeation chromatography (GPC) afforded M_{w}/Mₙ of 1591/930.

### Comparative Example 2

Following the procedure described in Example 1, EtoPhen (95.2 g, 0.279 mol), MTEOS (149.5 g, 0.838 mol), TEOS (155.2 g, 0.745 mol), 0.01M HCl (114.1 g), acetone (440.0 g) PGMEA (1100.0 g), PGEE (1000.0 g), and MTBE (500.0 g) were used. The obtained polymer solution was filtered with 0.2-micron filter and characterized by Gel permeation chromatography (GPC) afforded M_{w}/Mₙ of 1323/960.

### Example 5

Following the procedure described in Example 1, MTEOS (12.6 g, 0.070 mol), TEOS (59.6 g, 0.280 mol), PTTEOS (10.0 g, 0.024 mol), 0.01M HCl (38.8 g), and acetone (120.5 g) were used. The obtained polymer solution was filtered with 0.2-micron filter and characterized by Gel permeation chromatography (GPC) afforded M_{w}/Mₙ of 2425/1284.

### Example 6

Following the procedure described in Example 1, MTEOS (17.7 g, 0.099 mol), TEOS (77.5 g, 0.370 mol), PTTEOS (10.0 g, 0.024 mol), 0.01M HCl (50.5 g), and acetone (155.7 g) were used. The obtained polymer solution was filtered with 0.2-micron filter and characterized by Gel permeation chromatography (GPC) afforded M_{w}/Mₙ of 2591/1377.

### Example 7

Following the procedure described in Example 1, MTEOS (32.4 g, 0.180 mol), TEOS (129.2 g, 0.620 mol), PTTEOS (10.0 g, 0.024 mol), 0.01M HCl (84.2 g), and acetone (255.8 g) were used. The obtained polymer solution was filtered with 0.2-micron filter and characterized by Gel permeation chromatography (GPC) afforded M_{w}/Mₙ of 5683/2414.

### Example 8

Following the procedure described in example 1, PTTEOS (2.0 g, 0.005 mol), TEOS (77.5 g, 0.370 mol), MTEOS (16.4 g, 0.091 mol), Phenyl trimethoxysilane (PhTMOS, 5.4 g, 0.027 mol), 0.01M HCl (50.5 g), and acetone (101.3 g) were added. The obtained polymer solution was filtered with 0.2-micron filter and characterized by Gel permeation chromatography (GPC) afforded M_{w}/Mₙ of 1109/1846.

### Example 9

Following the procedure described in example 1, MTEOS (82.7 g, 0.460 mol), PhTMOS (5.4 g, 0.027 mol), PTTEOS (10.0 g, 0.005 mol), 0.01M HCl (40.4 g), and acetone (130.6 g) were used. The obtained polymer solution was filtered with 0.2-micron filter and characterized by Gel permeation chromatography (GPC) afforded M_{w}/Mₙ of 1587/931.

### Example 10 (PTTEOS as an Additive)

Preparation of additive solution with PTTEOS and use of it in formulation of siloxane-based polymer composition used as underlayer material for 193 nm.

2.8 g of PTTEOS (0.007 mol) and 1.62 g of maleic acid (0.014 mol) were dissolved in 17.6 g of propylene-glycol-methyl-ether acetate (PGMEA) by stirring in 50° C. water bath to give additive solution with 20% solid content. Additive solution was filtered with 0.45 μm PTFE-filter. 0.3 g of filtered additive solution was added to 100.0 g of siloxane-based polymer formulation with solid content of 1.94% yielding in a formulation with 0.25% of additives with respect to solid polymer.

### Comparative Example 3

Following the procedure described in example 1, PhTMOS (27.7 g, 0.139 mol), MTEOS (81.7 g, 0.458 mol), TEOS (290.6 g, 1.395 mol), 0.01M HCl (132.8 g), acetone (400.0 g) PGMEA (1100.0 g), and PGEE (1000.0 g), and were used. The obtained polymer solution was filtered with 0.2-micron filter and characterized by Gel permeation chromatography (GPC) afforded M_{w}/Mₙ of 1306/1912.

### Example 11

Following the procedure described in example 1, PTTEOS (5.0 g, 0.013 mol), TEOS (35.3 g, 0.169 mol), MTEOS (7.5 g, 0.041 mol), 0.01M HCl (23.0 g), and acetone (70.5 g) were used. The obtained polymer solution was filtered with 0.2-micron filter and characterized by Gel permeation chromatography (GPC) afforded M_{w}/Mₙ of 2475/1436.

### Example 12

Following the procedure described in example 1, PTTEOS (3.0 g, 0.008 mol), TEOS (62.0 g, 0.290 mol), MTEOS (57.0 g, 0.320 mol), PhTMOS (23.6 g, 0.110 mol), 0.01M HCl (68.7 g), and acetone (214.5 g) were added. The obtained polymer solution was filtered with 0.2-micron filter and characterized by Gel permeation chromatography (GPC) afforded M_{w}/Mₙ of 1639/1039.

### Example 13

Following the procedure described in example 1, PTTEOS (2.0 g, 0.005 mol), TEOS (77.6 g, 0.370 mol), MTEOS (16.4 g, 0.091 mol), EtoPhen (9.3 g, 0.027 mol), 0.01M HCl (50.5 g,), and acetone (155.7 g) were added. The obtained polymer solution was filtered with 0.2-micron filter and characterized by Gel permeation chromatography (GPC) afforded M_{w}/Mₙ of 1415/693.

The novel aromatic butterfly shape compound containing sulfur and nitrogen atoms exhibits a high refractive index as outlined above, In addition, the compound and the derivatives exhibits high absorption of UV light around the wavelengths below 400 nm. The combination of high refractive index and a high molar absorptivity yields compositions containing the novel aromatic butterfly shape compound containing sulfur and nitrogen atoms is useful in lithography applications where even small quantities of the said compound can be used to adjust the refractive index and absorption of light at 248 nm and 193 nm wavelengths frequently employed in lithography.

### Example 14

The solution obtained in Example 7 was spin coated on a wafer to a 9 nm thickness to yield a functional coating. On top of this, a chemically amplified photoresist was coated. The resist was exposed to 13.5 nm light. After a post exposure bake according to resist manufacturer, the coating was developed. A dose-to-size image of line and space patterns was obtained with a half pitch of 32 nm was obtained. The dose to obtain the dose-to-size image was 23% lower than that without the functional coating.

### Experimental

The measurements of Molecular weight was collected with gel permeation chromatography against polystyrene standards with known molecular weights using a Waters HPLC equipment including Waters 1515 isocratic HPLC pump, Waters 2414 refractive index detector, Water column block heater module, Waters 717plus Autosampler, Waters valve selector, Waters switching valve, Waters In-line Degasser AF and Waters Temperature control module II. It was equipped with Styragel HR columns (guard column, HR1, HR3, HR4) connected in series. Flow rate of THF eluent was 1.0 ml/min.

Film thickness measurement was carried out using J.A. Woollam M2000D-ESM-200AXY spectroscopic ellipsometer.

“Refractive index” (RI) is determined using a refractrometer at a wavelength of 633 nm. The RI can be calculated by, e.g. interferometry, the deviation method, or the Brewster Angle method from a polymeric film sample having a thickness of 400 nm.

The film contact angle can be measured by using KSV Instruments CAM100. The tool has an inaccuracy of +/−0.1 degrees and determines the angle formed by a water droplet at the boundary where liquid (DI-water), gas (air) and solid (thin film) intersect. A syringe with micro-screw was used to dispense a DI-water droplet on a film (coated typically on a silicon wafer) to determine static contact angle. Further, the contact angle automatically calculated by in built software from still images taken with a camera by using Young-Laplace equation for curve fitting. The resulting static contact angle is the average of left and right-side angle measurements. Three measurements were performed on each sample and the average value reported.

### Results

Polysiloxane compositions comprising various ratios of newly designed monomer can effectively tune refractive index (n) and extinction coefficient (k) at various wavelengths shown in Table 1 and 2 respectively. The refractive index of the composition at visible wavelengths increases as a function of an increase content of PTTEOS.

TABLE 1

| | Thickness | n at | k at | n at | k at |
|---|---|---|---|---|---|
| Example No. | nm | 450 nm | 450 nm | 633 nm | 633 nm |
| 1 | 90 | 1.70 | <0.001 | 1.66 | 0 |
| 2 | 47 | 1.62 | <0.001 | 1.59 | 0 |
| 3 | 16 | 1.54 | <0.001 | 1.52 | 0 |
| 4 | 89 | 1.57 | <0.001 | 1.54 | 0 |
| 5 | 16 | 1.47 | <0.001 | 1.46 | 0 |
| 6 | 52 | 1.46 | <0.001 | 1.45 | 0 |
| 7 | 16 | 1.44 | <0.001 | 1.42 | 0 |
| 8 | 120 | 1.57 | <0.001 | 1.53 | 0 |
| 9 | 66 | 1.45 | <0.001 | 1.44 | 0 |
| 10 (additive) | 25 | — | — | 1.46 | 0 |
| 11 | 256 | 1.50 | <0.001 | 1.49 | 0 |
| 12 | 81 | 1.48 | <0.001 | 1.46 | 0 |
| 13 | 87 | 1.51 | <0.001 | 1.49 | 0 |
| Comp. Ex. 1 | 120 | 1.69 | <0.001 | 1.65 | 0 |
| Comp. Ex. 2 | 119 | 1.58 | <0.001 | 1.54 | 0 |
| Comp. Ex. 3 | 36 | 1.48 | <0.001 | 1.44 | 0 |

TABLE 2

| | Thickness | n at | k at | n at | k at |
|---|---|---|---|---|---|
| Example No. | (nm) | 193 nm | 193 nm | 248 nm | 248 nm |
| 1 | 90 | 1.34 | 0.29 | 1.99 | 0.55 |
| 2 | 47 | 1.68 | 0.35 | 1.57 | 0.23 |
| 3 | 16 | 1.59 | 0.25 | 1.54 | 0.21 |
| 4 | 89 | 1.56 | 0.18 | 1.51 | 0.39 |
| 5 | 16 | 1.56 | 0.14 | 1.51 | 0.12 |
| 6 | 52 | 1.59 | 0.10 | 1.52 | 0.10 |
| 7 | 16 | 1.53 | 0.07 | 1.49 | 0.06 |
| 8 | 120 | 1.54 | 0.19 | 1.56 | 0.30 |
| 9 | 66 | 1.65 | 0.15 | 1.51 | 0.02 |
| 10 (additive) | 25 | 1.68 | 0.16 | — | — |
| 11 | 256 | 1.59 | 0.13 | 1.52 | 0.11 |
| 12 | 81 | 1.72 | 0.30 | 1.56 | 0.02 |
| 13 | 87 | 1.57 | 0.10 | 1.51 | 0.19 |
| Comp. Ex. 1 | 120 | 1.55 | 0.32 | 1.51 | 0.59 |
| Comp. Ex. 2 | 119 | 1.57 | 0.21 | 1.52 | 0.36 |
| Comp. Ex. 3 | 36 | 1.67 | 0.17 | 1.54 | 0 |

As will appear, a composition described in Example 3 showed higher refractive index (n) of 1.54 at 248 nm wavelength than a composition of comparative Example 2 of n of 1.52 at 248 nm, indicating its potential to be used in 248 nm or KrF lithography.

Additionally, upon incorporation of newly designed monomer at less than 1% in polymer composition presented in Table 2 Example 8 tunes the refractive index and extinction coefficient (k) to 1.54 and 0.19 at deep ultraviolet lithographic wavelength of 193 nm compared to a composition of comparative Example 3 of n and k are 1.67 and 0.17, respectively shown in Table 2 these tunable properties shows its potential to be employed in deep UV lithographic in particular 193 nm lithography applications.

When the newly designed sulfur and nitrogen containing compound was used as an external additive into the polymer composition of comparative Example 3 the water contact angle (CA) was improved to a value greater than 60° leading to more hydrophobic polysiloxane compositions presented in Table 3.

TABLE 3

| | Thickness | CA |
|---|---|---|
| Examples | nm | ° |
| 1 | 90 | 79 |
| 2 | 47 | 68 |
| 3 | 16 | — |
| 4 | 89 | 72 |
| 5 | 16 | — |
| 6 | 52 | 42 |
| 7 | 16 | — |
| 8 | 120 | 65 |
| 9 | 66 | 87 |
| 10 (additive) | 25 | 62 |
| 11 | 256 | — |
| 12 | 81 | 74 |
| 13 | 87 | 64 |
| Comp. Ex. 1 | 120 | — |
| Comp. Ex. 2 | 119 | 65 |
| Comp. Ex. 3 | 36 | 58 |

More importantly, upon composition of newly designed monomer as low as 1% into comparative Example 3 by hydrolysis and leading to significant enhancement in water contact angle greater than 60° of example 8 compared to parent polymer or comparative example 3 in Table 3. Thus, designed monomer can act as efficient surface modifier to achieve desired surface properties.

As will be understood from the preceding description of the present invention and the illustrative experimental examples, the present invention can be described by reference to the following embodiments:

1. Poly(organosiloxane) obtained by polymerization of a first silicon compound having the general formula II

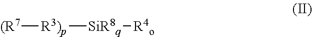

wherein
R³ stands for a bridging hydrocarbyl radical that can be independently selected from optionally functionalized linear, branched or cyclic, bivalent, saturated or unsaturated hydrocarbyl radicals, such as an optionally functionalized linear, branched or cyclic alkylene, alkenylene or alkynylene group; and optionally functionalized bivalent aromatic or polyaromatic groups
R⁴ stand for hydrogen, hydroxyl, halogen, alkoxy or acyloxy or a hydrocarbyl radical, wherein the hydrocarbyl radical can be independently selected from optionally functionalized linear, branched or cyclic alkyl groups, optionally functionalized aromatic or polyaromatic groups, or an optionally substituted polyaromatic hydrocarbyl radical having both nitrogen and sulfur atoms;
p and q are integers independently selected from the range of 1 to 3,
o is an integer of 1 or 2, and
the total value of p+q+o does not exceed 4,
R⁷ stands for an optionally substituted polyaromatic hydrocarbyl radical having both nitrogen and sulfur atoms; and
R³ stands for an alkoxy group, an acyloxy group, or a halogen group.

2. The poly(organosiloxane) according to embodiment 1, obtained by hydrolyzing the first silicon compound having the general formula II, with one or more second silicon compounds having the general formula III

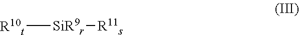

wherein
R⁹ stands for an alkoxy group, an acyloxy group, or a halogen group,
t is an integer of 0 to 3,
r is an integer of 1 to 4, and
s is an integer of 0 to 3,
wherein the total value of t+r+s may not exceed 4.
R¹⁰ and R¹¹ are independently selected from alkyl groups, aryl groups, aralkyl groups, halogenated alkyl groups, halogenated aryl groups, halogenated aralkyl groups, alkenyl groups, organic groups having one or more epoxy groups, mercapto groups, alkoxyaryl groups, acyloxyaryl groups, isocyanurate groups, hydroxy groups, cyclic amino groups, or cyano groups and combinations thereof; or
R¹⁰ and R¹¹ are independently selected from alkoxy groups, acyloxy groups, and halogen groups;

3. The poly(organosiloxane) according to embodiment 1 or 2, comprising an at least partially cross-linked organosiloxane polymer, said polymer having a molecular weight (Mw) of about 500 to 100,000 g/mol, in particular about 1,000 to 50,000 g/mol, measured against polystyrene standards.

4. The poly(organosiloxane) according to any of the preceding embodiments, having the general formula I

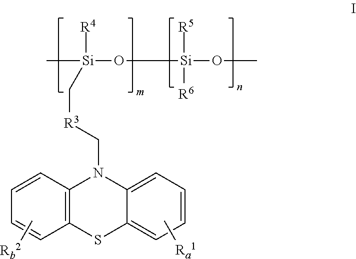

wherein
R¹ₐ and R²_{b} stand for halogen or hydrocarbyl radical that can be independently selected from optionally functionalized linear, branched or cyclic alkyl groups, optionally functionalized aromatic or polyaromatic groups;
R³ stands for a bridging hydrocarbyl radical that can be independently selected from optionally functionalized linear, branched or cyclic, bivalent, saturated or unsaturated hydrocarbyl radicals, such as an optionally functionalized linear, branched or cyclic alkylene, alkenylene or alkynylene group; and optionally functionalized bivalent aromatic or polyaromatic groups;
R⁴ stand for hydrogen, hydroxyl, halogen, alkoxy or acyloxy or a hydrocarbyl radical, wherein the hydrocarbyl radical can be independently selected from optionally functionalized linear, branched or cyclic alkyl groups, optionally functionalized aromatic or polyaromatic groups, or an optionally substituted polyaromatic hydrocarbyl radical having both nitrogen and sulfur atoms;
R⁵ and R⁶ stand for hydrogen, hydroxyl, halogen, alkoxy or acyloxy or a hydrocarbyl radical, wherein the hydrocarbyl radical can be independently selected from optionally functionalized linear, branched or cyclic alkyl groups, optionally functionalized aromatic or polyaromatic groups;
a and b are independently selected from integers having a value in the range from 0 to 4; and
m and n are independently selected from integers having a value in the range from 1 to 1000.

5. The poly(organosiloxane) according to any of the preceding embodiments, wherein R⁷ stands for an optionally substituted polyaromatic hydrocarbyl radical having both nitrogen and sulfur atoms exhibiting a butterfly shaped aromatic structure with a dihedral angle of <165° between two benzene rings and a C—S—C angle of <110°.

6. Poly(organosiloxane) obtained by polymerization of a first silicon compound having the general formula II

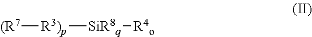

wherein
R³ stands for a bridging hydrocarbyl radical that can be independently selected from optionally functionalized linear, branched or cyclic, bivalent, saturated or unsaturated hydrocarbyl radicals, such as an optionally functionalized linear, branched or cyclic alkylene, alkenylene or alkynylene group; and optionally functionalized bivalent aromatic or polyaromatic groups
R⁴ stand for hydrogen, hydroxyl, halogen, alkoxy or acyloxy or a hydrocarbyl radical, wherein the hydrocarbyl radical can be independently selected from optionally functionalized linear, branched or cyclic alkyl groups, optionally functionalized aromatic or polyaromatic groups, or an optionally substituted polyaromatic hydrocarbyl radical having both nitrogen and sulfur atoms;
p and q are integers independently from the range of 1 to 3,
o is an integer of 1 or 2, and
the total value of p+q+o does not exceed 4,
R⁷ stands for an optionally substituted polyaromatic hydrocarbyl radical having both nitrogen and sulfur atoms exhibiting a butterfly shaped aromatic structure with a dihedral angle of <165° between two benzene rings and a C—S—C angle of <110°, and
R⁸ stands for an alkoxy group, an acyloxy group, or a halogen group.

7. The poly(organosiloxane) according to any of the preceding embodiments, wherein the first silicon compound is selected from the group of compounds having the general formulas

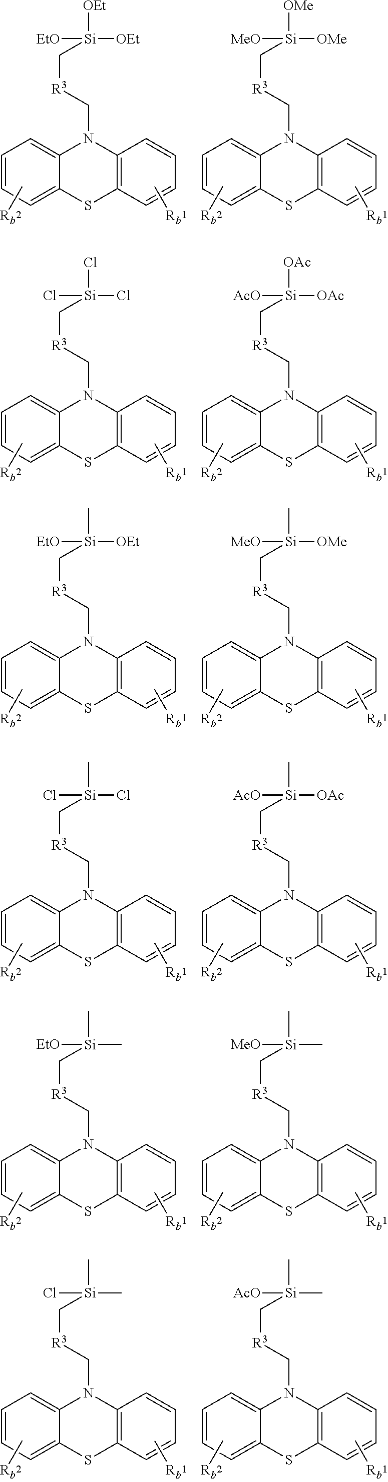

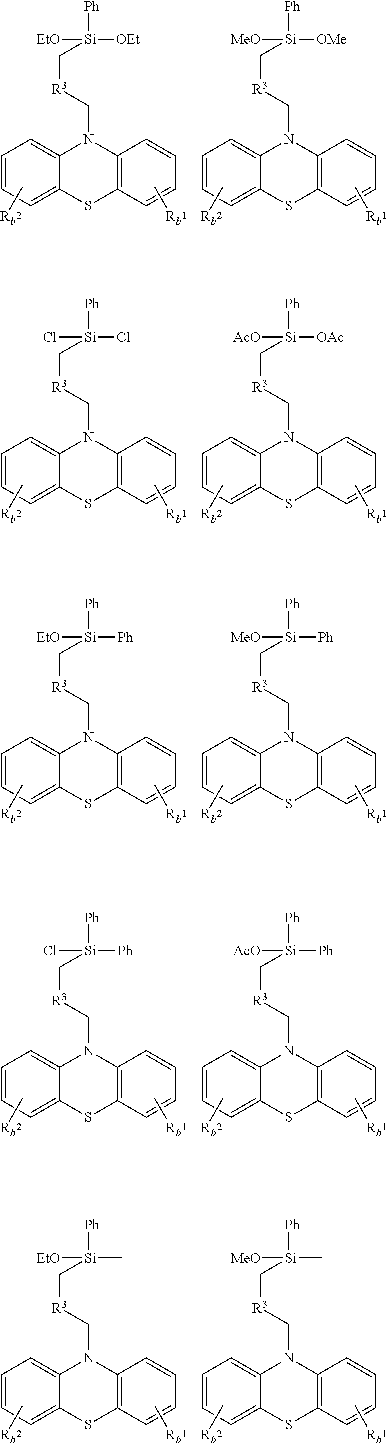

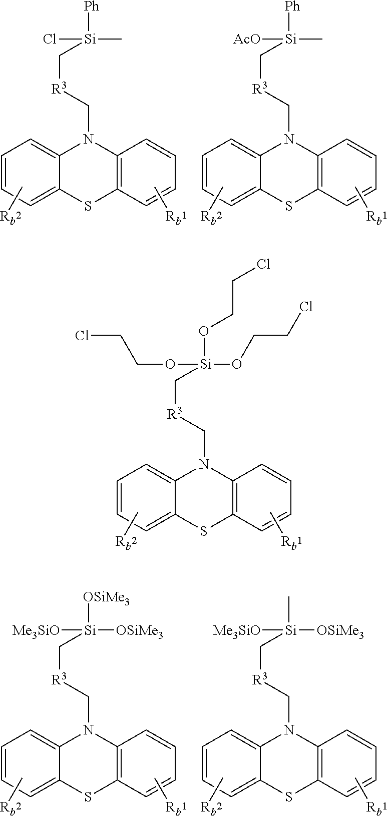

wherein
Rₐ¹ and R_{b}² and R³ have the same meaning as above in formula I.

8. The poly(organosiloxane) according to any of the preceding embodiments, wherein the second silicon compound is selected from the group of tetramethoxysilane, tetrachlorosilane, tetraacetoxysilane, tetraethoxysilane, tetra-n-propoxysilane, tetraisopropoxysilane, tetra-n-butoxysilane, methyltrimethoxysilane, methyltriethoxysilane, methyltrichlorosilane, methyltriacetoxysilane, methyltripropoxysilane, methyltributoxysilane, methyltriphenoxysilane, methyltribenzyloxysilane, ethyltrimethoxysilane, ethyltriethoxysilane, phenyltrimethoxysilane, phenyltrichlorosilane, phenyltriacetoxysilane, phenyltriethoxysilane, γ-mercaptopropyltrimethoxysilane, γ-mercaptopropyltriethoxysilane, β-cyanoethyltriethoxysilane, dimethyldimethoxysilane, phenylmethyldimethoxysilane, dimethyldiethoxysilane, phenylmethyldiethoxysilane, dimethyldiacetoxysilane, γ-mercaptopropylmethyldimethoxysilane, γ-mercaptomethyldiethoxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, and phenylsulfonylaminopropyltriethoxysilane, vinyltrimethoxysilane, vinyltrichlorosilane, vinyltriacetoxysilane, vinyltriethoxysilane, methylvinyldimethoxysilane, methylvinyldiethoxysilane, γ-methacryloxypropyltrimethoxysilane, γ-methacryloxypropylmethyldimethoxysilane, γ-methacryloxypropylmethyldiethoxysilane, (methacryloxymethyl)methyldiethoxysilane, (methacryloxymethyl)methyldimethoxysilane, methacryloxymethyltriethoxysilane, methacryloxymethyltrimethoxysilane, methacryloxypropyltrichlorosilane, methacryloxypropyltriethoxysilane, methacryloxypropyltriisopropoxysilane, γ-chloropropyltrimethoxysilane, γ-chloropropyltriethoxysilane, γ-chloropropyltriacetoxysilane, chloromethyltrimethoxysilane, chloromethyltriethoxysilane, γ-chloropropylmethyldimethoxysilane, γ-chloropropylmethyldiethoxysilane, 3,3,3-trifluoropropyltrimethoxysilane, 4-acetoxyphenylethyltrimethoxysilane, 4-acetoxyphenylethyltriethoxysilane 4-(acetoxyphenylethyl)methyldichlorosilane, 4-(acetoxyphenylethyl)methyldimethoxysilane, 4-(acetoxyphenylethyl)methyldiethoxysilane, triethoxysilylpropylcarbamate, triethoxysilylpropylmaleamic acid, N-(3-triethoxysilylpropyl)-4-hydroxybutyramide, N-(3-triethoxysilylpropyl)gluconamide, (3-triethoxysilyl)propylsuccinic anhydride, ureidopropyltriethoxysilane, ureidopropyltrimethoxysilane, 3-hydroxy-3,3-bis(trifluoromethyl)propyl triethoxysilane, 4-(methoxymethoxy)trimethoxysilylbenzene and 6-(methoxymethoxy)-2-(trimethoxysilyl)naphthalene and combinations thereof.

9. The poly(organosiloxane) according to any of the preceding embodiments, wherein the residue R⁷ of Formula (II) is derived from compounds of the following group:

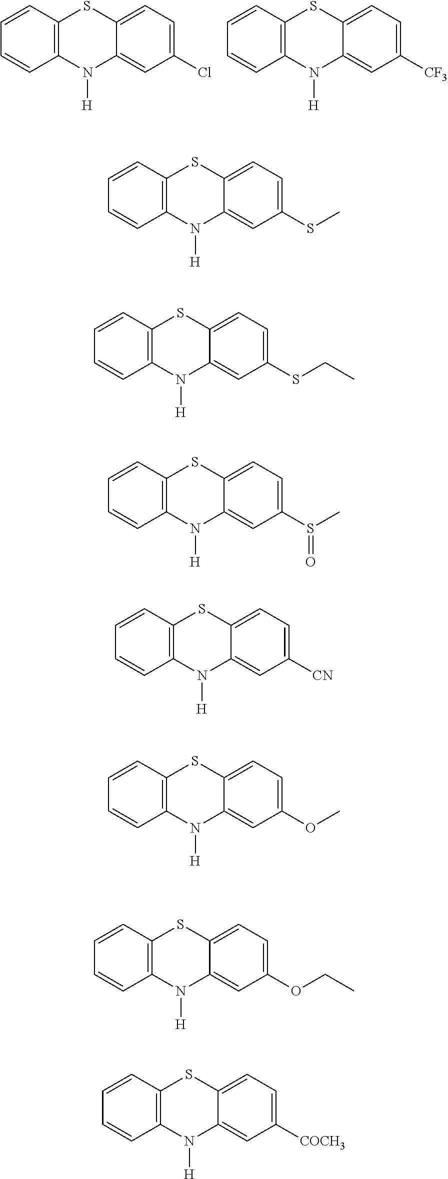

10. A composition comprising a poly(organosiloxane) resin in liquid phase, comprising a poly(organosiloxane) according to any of the preceding embodiments in the liquid phase formed by at least one organic solvent for the poly(organosiloxane) resin, optionally in mixture with water.

11. The composition according to embodiment 10, wherein the liquid phase comprises an organic liquid and from about 0.001 M to about 1 M of said poly(organosiloxane), and said polymer solution having a viscosity from about 0.5 centipoises (cP) to about 150 cP, said organic liquid preferably having a flash point of at least 10° C. and a vapor pressure at 20° C. of less than about 10 kPa.

12. The coating/film obtained by casting/coating of the composition to the substrate according to embodiments 10 or 11, which composition is formulated for use in a method of a coating a substrate by casting.

13. The composition according to any of embodiments 10 to 12, obtained after a thermal curing step at a temperature above 100° C.

14. The composition according to any of embodiments 10 to 13, exhibiting a silicon content higher than 20%, more preferably higher than 25%, most preferably more than 30% calculated from the dry weight of the composition.

15. The composition according to any of embodiments 10 to 14, wherein the liquid phase comprises a solvent selected from the group of PGMEA, PGEE, THF and mixtures thereof.

16. The composition according to any of embodiments 10 to 15, wherein the solid content of the polymer in the liquid phase is 1 to 4% by weight.

17. A polymer film, comprising a poly(organosiloxane) according to any of embodiments 1 to 9.

18. The polymer film according to embodiment 17, comprising a film obtained by depositing a composition according to any of embodiments 10 to 16 on a substrate.

19. The polymer film according to embodiment 18, forming an antireflective coating in photolithography before or after the photoresist layer in order to reduce standing wave and thin-film interference.

20. The polymer film according to any of embodiments 17 to 19 obtained by spin coating of a composition according to any of embodiments 10 to 16 on a substrate, in particular on a silicon substrate.

21. A resist underlayer coating composition for lithography, comprising:
a silane, at least one among a hydrolyzable organosilane, a hydrolysis product thereof, and a hydrolysis-condensation product thereof, wherein
the silane includes the silane compound of Formula (I) alone or as a copolymer with one or more silane compound of Formulas (II) and/or (Ill) according to any of embodiments 1 to 9.

22. The resist underlayer film forming composition according to embodiment 21, obtained by applying the resist underlayer film composition as disclosed in any one of embodiments 10 to 16 onto a semiconductor substrate, and baking the composition.

23. A method for producing a semiconductor device, the method comprising:
applying the resist underlayer film forming composition as disclosed in any of embodiments 10 to 16 onto a semiconductor substrate and baking the composition to form a resist underlayer film;
applying a composition for a resist onto the resist underlayer film to form a resist film;
exposing the resist film to light or electron beam radiation at, e.g., 13.5 nm, 193 nm, 248 nm 365 nm;
developing the resist film after the exposing to obtain a patterned resist film;
etching the resist underlayer film according to a pattern of the patterned resist film; and
processing the semiconductor substrate according to a pattern of the resist film and the resist underlayer film.

24. A method for producing a semiconductor device, the method comprising:
forming an organic underlayer film on a semiconductor substrate;
applying the resist underlayer film forming composition according to any of embodiments 10 to 16 onto the organic underlayer film and baking the composition to form a resist underlayer film;
applying a composition for a resist onto the resist underlayer film to form a resist film;
exposing the resist film to light or electron beam radiation at, e.g., 13.5 nm, 193 nm, 248 nm 365 nm;
developing the resist film after the exposing to obtain a patterned resist film;
etching the resist underlayer film according to a pattern of the patterned resist film;
etching the organic underlayer film according to a pattern of the pattered resist underlayer film; and
processing the semiconductor substrate according to a pattern of the patterned organic underlayer film.

25. A method for producing an optical or semiconductor device, the method comprising:
applying a spin on carbon (SOC) with various thermal stabilities, e.g. High temperature (350-400° C.) SOC, or α-carbon layer obtained by CVD. on a substrate
applying a composition of high silicon content layer or silicon oxynitride or various metal oxide layer
applying a functional coating layer comprising a poly(organosiloxane) according to any one of embodiments 1 to 10
applying a composition for a resist onto the resist underlayer functional layer to obtain a resist film
exposing the resist film to light at, e.g., 13.5 nm, 193 nm, 248 nm, or 365 nm, or electron beam radiation
developing the resist film after the exposing to obtain a patterned resist film to achieve a 15-30% decrease in dose compared to that achieved without functional layer;
etching the resist underlayer film according to a pattern of the patterned resist film;
and
processing the substrate according to a pattern of the resist film and the resist underlayer film.

26. Use of a poly(organosiloxane) according to any of embodiments 1 to 9 or a composition according to any of embodiments 10 to 16 as an additive, in particular to tune the polymer film thickness, index of refraction (n), molar absorptivity (k), and contact angle (CA) of a siloxane-based photoresist polymer.

27. Use of a poly(organosiloxane) according to any of embodiments 1 to 9 or a composition according to any of embodiments 10 to 16 as an additive in a siloxane polymer composition to obtain a film having a thickness of 30 to 60 nm, especially 35 nm, and preferably exhibiting an essentially constant molecular weight and contact angle over a time period of 42 days at room temperature.

28. A method for producing an optical element or an optically active device:
applying the resist underlayer film forming composition as disclosed in any of embodiments 10 to 16 onto a substrate and baking the composition to form a resist underlayer film;
applying a composition for a resist onto the resist underlayer film to form a resist film;
exposing the resist film to light or electron beam radiation at, e.g., 13.5 nm, 193 nm, 248 nm, 365 nm;
developing the resist film after the exposing to obtain a patterned resist film;
etching the resist underlayer film according to a pattern of the patterned resist film; and
processing the substrate according to a pattern of the resist film and the resist underlayer film.

29. A method according to embodiment 28, where the substrate is TiO₂, Si, GaAs or other substrate used in diffractive or meta optical element.

30. A method for patterning a semiconductor substrate, the method comprising:
forming an organic underlayer film on a semiconductor substrate;
forming an inorganic oxide containing middle layer on the organic underlayer;
applying the resist underlayer film forming composition according to any of embodiments 10 to 16 onto the inorganic oxide containing middle layer film and baking the composition to form a resist underlayer film;
applying a composition for a resist onto the resist underlayer film to form a resist film;
exposing the resist film to light or electron beam radiation at, e.g., 13.5 nm, 193 nm, 248 nm 365 nm:
developing the resist film after the exposing to obtain a patterned resist film;
etching the resist underlayer film according to a pattern of the patterned resist film;
etching the inorganic oxide containing middle layer film according to a pattern of the patterned resist film;
etching the organic underlayer film according to a pattern of the pattered resist underlayer film; and
processing the semiconductor substrate according to a pattern of the patterned organic underlayer film.

### Abbreviations

ARC Anti-Reflecting Coating
BARC Bottom Anti-Reflecting Coating
CA Contact Angle
CMOS Complementary Metal Oxide Semiconductor
SOC Silicon-On-Carbon
GC-MS Gas Chromatography Mass Spectroscopy
GPC Gel permeation chromatography
PGMEA Propylene glycol monomethyl ether acetate
PGEE Pylene glycol n-ethyl ether
THF Tetrahydrofuran
EtoPhen Phenanthrenyltriethoxysilane
GPTMOS Glycidoxypropyltrimethoxysilane
MTEOS Methoxytriethoxysilane
PhTMOS Phenyltrimethoxysilane
TMOS Tetramethoxysilane
TEOS Tetraethoxy silane
PTTEOS 10-(3-(triethoxysilyl) propyl)-10H-phenothiazine

### CITATIONS

US 2005/0042538 A1
US 2007/0148586 A1
US 2010/167203 A1

1. A resist underlayer coating composition for lithography, comprising:
a silane, at least one among a hydrolyzable organosilane, a hydrolysis product thereof, and a hydrolysis-condensation product thereof, wherein
the silane includes the silane compound of Formula (I) alone 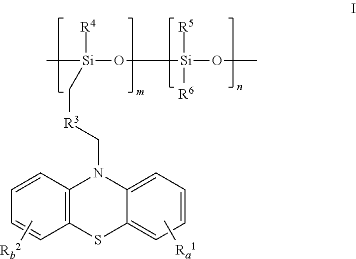
wherein
Rₐ¹ and R_{b}² stand for halogen or hydrocarbyl radical that can be independently selected from optionally functionalized linear, branched or cyclic alkyl groups, optionally functionalized aromatic or polyaromatic groups;
R³ stands for a bridging hydrocarbyl radical that can be independently selected from optionally functionalized linear, branched or cyclic, bivalent, saturated or unsaturated hydrocarbyl radicals, and optionally functionalized bivalent aromatic or polyaromatic groups;
R⁴ stands for hydrogen, hydroxyl, halogen, alkoxy or acyloxy or a hydrocarbyl radical, wherein the hydrocarbyl radical can be independently selected from optionally functionalized linear, branched or cyclic alkyl groups, optionally functionalized aromatic or polyaromatic groups, or an optionally substituted polyaromatic hydrocarbyl radical having both nitrogen and sulfur atoms;
R⁵ and R⁶ stand for hydrogen, hydroxyl, halogen, alkoxy or acyloxy or a hydrocarbyl radical, wherein the hydrocarbyl radical can be independently selected from optionally functionalized linear, branched or cyclic alkyl groups, optionally functionalized aromatic or polyaromatic groups;
a and b are independently selected from integers having a value in the range from 0 to 4; and
m and n are independently selected from integers having a value in the range from 1 to 1000
or as a copolymer with one or more silane compounds of Formulas (II) and/or (III), the silane compound of Formula II having the formula; 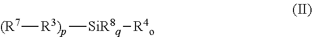
wherein
R³ and R⁴ have the same meaning as in Formula I,
p and q are integers independently from the range of 1 to 3,
o is an integer of 1 or 2, and
the total value of p+q+o does not exceed 4,
R⁷ stands for an optionally substituted polyaromatic hydrocarbyl radical having both nitrogen and sulfur atoms, and
R⁸ stands for an alkoxy group, an acyloxy group, or a halogen group;
and the silane compound of Formula III having the formula 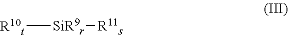
wherein
R⁹ stands for an alkoxy group, an acyloxy group, or a halogen group,
t is an integer of 0 to 3,
r is an integer of 1 to 4, and
s is an integer of 0 to 3,
wherein the total value of t+r+s may not exceed 4.
R¹⁰ and R¹¹ are independently selected from alkyl groups, aryl groups, aralkyl groups, halogenated alkyl groups, halogenated aryl groups, halogenated aralkyl groups, alkenyl groups, organic groups having one or more epoxy groups, mercapto groups, alkoxyaryl groups, acyloxyaryl groups, isocyanurate groups, hydroxy groups, cyclic amino groups, or cyano groups and combinations thereof; or
R¹⁰ and R¹¹ are independently selected from alkoxy groups, acyloxy groups, and halogen groups.

2. The resist underlayer coating composition according to claim 1, comprising an at least partially cross-linked organosiloxane polymer, said polymer having a molecular weight (Mw) of about 500 to 100,000 g/mol, measured against polystyrene standards.

3. The resist underlayer coating composition according to claim 1, wherein R⁷ stands for an optionally substituted polyaromatic hydrocarbyl radical having both nitrogen and sulfur atoms exhibiting a butterfly shaped aromatic structure with a dihedral angle of <165° between two benzene rings and a C—S—C angle of <110°.

4. The resist underlayer coating composition according to claim 1, wherein the compound of Formula II is selected from the group of compounds having the general formulas 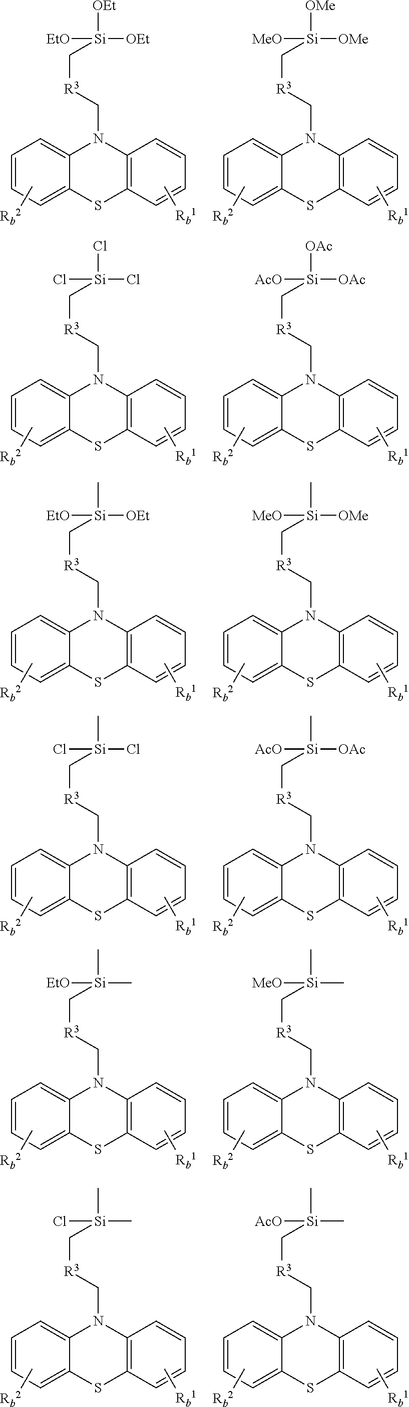 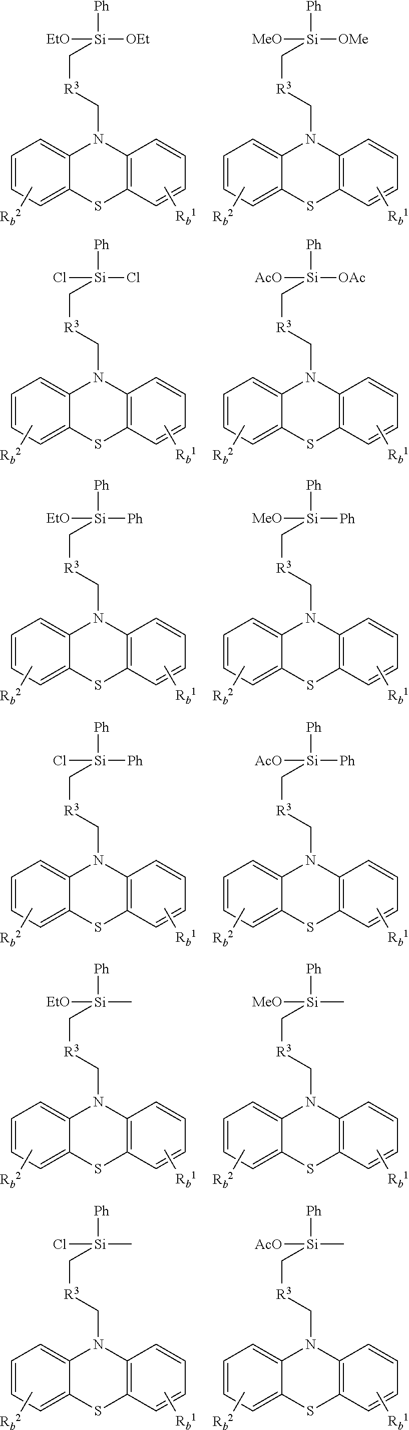 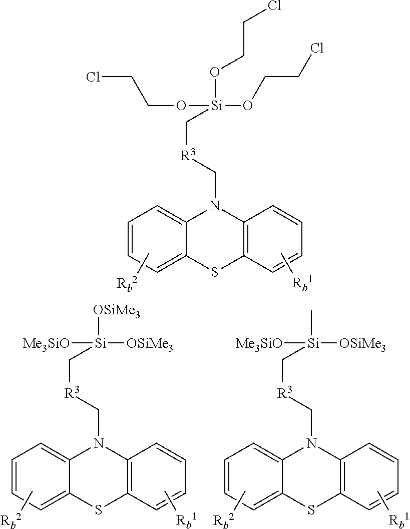
wherein
Rₐ¹ and R_{b}² and R³ have the same meaning as in formula I.

5. The resist underlayer coating composition according to claim 1, wherein the compound of Formula III is selected from the group of tetramethoxysilane, tetrachlorosilane, tetraacetoxysilane, tetraethoxysilane, tetra-n-propoxysilane, tetraisopropoxysilane, tetra-n-butoxysilane, methyltrimethoxysilane, methyltriethoxysilane, methyltrichlorosilane, methyltriacetoxysilane, methyltripropoxysilane, methyltributoxysilane, methyltriphenoxysilane, methyltribenzyloxysilane, ethyltrimethoxysilane, ethyltriethoxysilane, phenyltrimethoxysilane, phenyltrichlorosilane, phenyltriacetoxysilane, phenyltriethoxysilane, γ-mercaptopropyltrimethoxysilane, γ-mercaptopropyltriethoxysilane, β-cyanoethyltriethoxysilane, dimethyldimethoxysilane, phenylmethyldimethoxysilane, dimethyldiethoxysilane, phenylmethyldiethoxysilane, dimethyldiacetoxysilane, γ-mercaptopropylmethyldimethoxysilane, γ-mercaptomethyldiethoxysilane, glycidoxymethyltrimethoxysilane, glycidoxymethyltriethoxysilane, α-glycidoxyethyltrimethoxysilane, α-glycidoxyethyltriethoxysilane, β-glycidoxyethyltrimethoxysilane, β-glycidoxyethyltriethoxysilane, α-glycidoxypropyltrimethoxysilane, α-glycidoxypropyltriethoxysilane, β-glycidoxypropyltrimethoxysilane, β-glycidoxypropyltriethoxysilane, γ-glycidoxypropyltrimethoxysilane, γ-glycidoxypropyltriethoxysilane, γ-glycidoxypropyltripropoxysilane, γ-glycidoxypropyltributoxysilane, γ-glycidoxypropyltriphenoxysilane, α-glycidoxybutyltrimethoxysilane, α-glycidoxybutyltriethoxysilane, β-glycidoxybutyltriethoxysilane, γ-glycidoxybutyltrimethoxysilane, γ-glycidoxybutyltriethoxysilane, δ-glycidoxybutyltrimethoxysilane, δ-glycidoxybutyltriethoxysilane, (3,4-epoxycyclohexyl)methyltrimethoxysilane, (3,4-epoxycyclohexyl)methyltriethoxysilane, β-(3,4-epoxycyclohexyl)ethyltrimethoxysilane, β-(3,4-epoxycyclohexyl)ethyltriethoxysilane, β-(3,4-epoxycyclohexyl)ethyltripropoxysilane, β-(3,4-epoxycyclohexyl)ethyltributoxysilane, β-(3,4-epoxycyclohexyl)ethyltriphenoxysilane, γ-(3,4-epoxycyclohexyl)propyltrimethoxysilane, γ-(3,4-epoxycyclohexyl)propyltriethoxysilane, δ-(3,4-epoxycyclohexyl)butyltrimethoxysilane, δ-(3,4-epoxycyclohexyl)butyltriethoxysilane, glycidoxymethylmethyldimethoxysilane, glycidoxymethylmethyldiethoxysilane, α-glycidoxyethylmethyldimethoxysilane, α-glycidoxyethylmethyldiethoxysilane, β-glycidoxyethylmethyldimethoxysilane, β-glycidoxyethylethyldimethoxysilane, α-glycidoxypropylmethyldimethoxysilane, α-glycidoxypropylmethyldiethoxysilane, β-glycidoxypropylmethyldimethoxysilane, β-glycidoxypropylethyldimethoxysilane, γ-glycidoxypropylmethyldimethoxysilane, γ-glycidoxypropylmethyldiethoxysilane, γ-glycidoxypropylmethyldipropoxysilane, γ-glycidoxypropylmethyldibutoxysilane, γ-glycidoxypropylmethyldiphenoxysilane, γ-glycidoxypropylethyldimethoxysilane, γ-glycidoxypropylethyldiethoxysilane, γ-glycidoxypropylvinyldimethoxysilane, γ-glycidoxypropylvinyldiethoxysilane, and phenylsulfonylaminopropyltriethoxysilane, vinyltrimethoxysilane, vinyltrichlorosilane, vinyltriacetoxysilane, vinyltriethoxysilane, methylvinyldimethoxysilane, methylvinyldiethoxysilane, γ-methacryloxypropyltrimethoxysilane, γ-methacryloxypropylmethyldimethoxysilane, γ-methacryloxypropylmethyldiethoxysilane, (methacryloxymethyl)methyldiethoxysilane, (methacryloxymethyl)methyldimethoxysilane, methacryloxymethyltriethoxysilane, methacryloxymethyltrimethoxysilane, methacryloxypropyltrichlorosilane, methacryloxypropyltriethoxysilane, methacryloxypropyltriisopropoxysilane, γ-chloropropyltrimethoxysilane, γ-chloropropyltriethoxysilane, γ-chloropropyltriacetoxysilane, chloromethyltrimethoxysilane, chloromethyltriethoxysilane, γ-chloropropylmethyldimethoxysilane, γ-chloropropylmethyldiethoxysilane, 3,3,3-trifluoropropyltrimethoxysilane, 4-acetoxyphenylethyltrimethoxysilane, 4-acetoxyphenylethyltriethoxysilane 4-(acetoxyphenylethyl)methyldichlorosilane, 4-(acetoxyphenylethyl)methyldimethoxysilane, 4-(acetoxyphenylethyl)methyldiethoxysilane, triethoxysilylpropylcarbamate, triethoxysilylpropylmaleamic acid, N-(3-triethoxysilylpropyl)-4-hydroxybutyramide, N-(3-triethoxysilylpropyl)gluconamide, (3-triethoxysilyl)propylsuccinic anhydride, ureidopropyltriethoxysilane, ureidopropyltrimethoxysilane, 3-hydroxy-3,3-bis(trifluoromethyl)propyl triethoxysilane, 4-(methoxymethoxy)trimethoxysilylbenzene and 6-(methoxymethoxy)-2-(trimethoxysilyl)naphthalene and combinations thereof.

6. The resist underlayer coating composition according to claim 1, wherein the R⁷ of Formula (II) is derived from compounds of the following group:

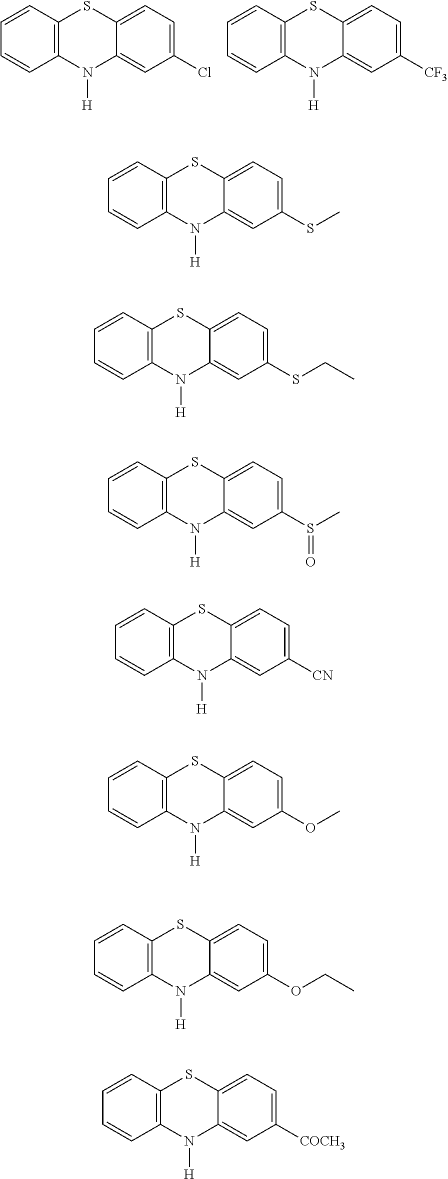

7. The resist underlayer coating composition according to claim 1, obtained after a thermal curing step at a temperature above 100° C.

8. The resist underlayer coating composition according to claim 1, exhibiting a silicon content higher than 20%, calculated from the dry weight of the composition.

9. The resist underlayer coating composition according to claim 1, wherein the composition has been obtained by applying the resist underlayer coating composition in a liquid phase comprising at least one organic solvent, onto a semiconductor substrate, and baking the composition.

10. The resist underlayer coating composition according to claim 9, wherein the liquid phase comprises an organic liquid and from about 0.001 M to about 1 M of the silane polymer, said polymer solution having a viscosity from about 0.5 centipoises (cP) to about 150 cP, said organic liquid preferably having a flash point of at least 10° C. and a vapor pressure at 20° C. of less than about 10 kPa.

11. The resist underlayer coating composition according to claim 9, wherein the liquid phase comprises a solvent selected from the group of PGMEA, PGEE, THE and mixtures thereof.

12. The resist underlayer coating composition according to claim 9, wherein the solid content of the silane polymer in the liquid phase is 1 to 4% by weight.

13. A method for producing a semiconductor device, the method comprising:
applying the resist underlayer film forming composition as claimed in claim 1 onto a semiconductor substrate and baking the composition to form a resist underlayer film;
applying a composition for a resist onto the resist underlayer film to form a resist film;
exposing the resist film to light or electron beam radiation;
developing the resist film after the exposing to obtain a patterned resist film;
etching the resist underlayer film according to a pattern of the patterned resist film; and
processing the semiconductor substrate according to a pattern of the resist film and the resist underlayer film.

14. A method for producing a semiconductor device, the method comprising:
forming an organic underlayer film on a semiconductor substrate;
applying the resist underlayer film forming composition according to claim 1 onto the organic underlayer film and baking the composition to form a resist underlayer film;
applying a composition for a resist onto the resist underlayer film to form a resist film;
exposing the resist film to light or electron beam radiation;
developing the resist film after the exposing to obtain a patterned resist film;
etching the resist underlayer film according to a pattern of the patterned resist film;
etching the organic underlayer film according to a pattern of the pattered resist underlayer film; and
processing the semiconductor substrate according to a pattern of the patterned organic underlayer film.

15. A method for producing an optical or semiconductor device, the method comprising:
applying a spin on carbon (SOC) with various thermal stabilities on a substrate
applying a composition of high silicon content layer or silicon oxynitride or various metal oxide layer
applying a functional coating layer comprising a composition according to claim 1
applying a composition for a resist onto the resist underlayer functional layer to obtain a resist film
exposing the resist film to light or electron beam radiation
developing the resist film after the exposing to obtain a patterned resist film to achieve a 15-30% decrease in dose compared to that achieved without a functional layer;
etching the resist underlayer film according to a pattern of the patterned resist film; and
processing the substrate according to a pattern of the resist film and the resist underlayer film.

16. (canceled)

17. (canceled)

18. A method for producing an optical element or an optically active device:
applying the resist underlayer film forming composition as claimed in claim 1 onto a substrate and baking the composition to form a resist underlayer film;
applying a composition for a resist onto the resist underlayer film to form a resist film;
exposing the resist film to light or electron beam radiation;
developing the resist film after the exposing to obtain a patterned resist film;
etching the resist underlayer film according to a pattern of the patterned resist film; and
processing the substrate according to a pattern of the resist film and the resist underlayer film.

19. The method according to claim 18, wherein the substrate is TiO₂, Si, GaAs or other substrate used in diffractive or meta optical element.

20. A method for patterning a semiconductor substrate, the method comprising:
forming an organic underlayer film on a semiconductor substrate;
forming an inorganic oxide containing middle layer on the organic underlayer;
applying the resist underlayer film forming composition according to claim 1 onto the inorganic oxide containing middle layer film and baking the composition to form a resist underlayer film;
applying a composition for a resist onto the resist underlayer film to form a resist film;
exposing the resist film to light or electron beam radiation:
developing the resist film after the exposing to obtain a patterned resist film;
etching the resist underlayer film according to a pattern of the patterned resist film;
etching the inorganic oxide containing middle layer film according to a pattern of the patterned resist film;
etching the organic underlayer film according to a pattern of the pattered resist underlayer film; and
processing the semiconductor substrate according to a pattern of the patterned organic underlayer film.
